(19) United States
(12) Patent Application Publication
(10) Pub. No.: US 2026/0032941 A1
(43) Pub. Date: Jan. 29, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Tzu-Ging LIN, Kaohsiung (TW); Chun-Liang LAI, Hsinchu (TW); Yen Ju CHEN, Hsinchu (TW); Jun-Ye LIU, Hsinchu (TW); Yun-Chen WU, Hsinchu (TW)

(21) Appl. No.: 18/954,778

(22) Filed: Nov. 21, 2024

Related U.S. Application Data
(60) Provisional application No. 63/676,385, filed on Jul. 28, 2024.

(51) Int. Cl. H01L 29/775; H01L 29/06; H01L 29/08; H01L 29/423; H01L 29/66; H01L 29/786

(52) U.S. Cl. CPC H10D 30/43; H10D 30/014; H10D 30/6735; H10D 30/6757; H10D 62/121; H10D 62/151; H10D 64/017

(57) ABSTRACT

Embodiments of the present disclosure relate to a semiconductor device structure. The structure includes a substrate, an insulating material disposed on the substrate, a first fin structure extending upwardly from the substrate through the insulating material, a second fin structure extending upwardly from the substrate through the insulating material, a source/drain (S/D) feature disposed between the first and second fin structures, and an isolation trench structure extending through the first fin structure and into the substrate, wherein the isolation trench structure has a doped sidewall region disposed between and in contact with the S/D feature and the isolation trench structure.

### CROSS-REFERENCE TO RELATED APPLICATIONS

This application claims priority to U.S. Provisional Application Ser. No. 63/676,385 filed Jul. 28, 2024, which is incorporated by reference in their entirety.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, continued reduction of the gate pitch is necessary. Various schemes, such as poly on diffusion edge (PODE) and continuous poly on diffusion edge (CPODE), have been used to scale the gate pitch while preventing leakage current between transistors. However, such schemes often involve both high and low selective etch processes for aggressively scaled circuits and devices, which may lead to high risk of source/drain damage.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, and 6 are perspective views of various stages of manufacturing a semiconductor device structure, in accordance with some embodiments.

FIGS. 7A, 8A, 9A, and 10A are cross-sectional side views of various stages of manufacturing the semiconductor device structure taken along line A-A of FIG. 6, in accordance with some embodiments.

FIGS. 7B, 8B, 9B, and 10B are cross-sectional side views of various stages of manufacturing the semiconductor device structure taken along line B-B of FIG. 6, in accordance with some embodiments.

FIGS. 7C, 8C, 9C, and 10C are cross-sectional side views of various stages of manufacturing the semiconductor device structure taken along line C-C of FIG. 6, in accordance with some embodiments.

FIGS. 11A-11B, 12A-12B, 13A-13B, 14A-14B, 15A-15B, 16A-16B, 17A-17B, 18A-18B, 19A-19B, 20A-20B, 21A-21B, 22A-22B, and 23A-23B are cross-sectional side views of one of various stages of manufacturing the semiconductor device structure of FIGS. 10A and 10B showing multiple fin structures disposed along the X and Y directions, respectively, in accordance with some embodiments.

FIG. 17A-1 illustrates an enlarged view of a portion of the semiconductor device structure showing a protection barrier in the sidewalls of the isolation trenches.

FIGS. 18B-1 and 18B-2 illustrate the isolation trenches in accordance with some alternative embodiments.

FIGS. 24A, 25A, 26A, 27A, and 28A illustrate the use of sacrificial dielectric layers in accordance with some alternative embodiments.

FIGS. 29A-29B, 30A-30B, 31A-31B, 32A-32B, 33A-33B, 34A-34B, 35A-35B, and 36A-36B are cross-sectional side views of one of various stages of manufacturing the semiconductor device structure of FIGS. 10A and 10B showing multiple fin structures disposed along the X and Y directions, respectively, in accordance with some alternative embodiments.

FIG. 37 is a top view of the semiconductor device structure in accordance with some embodiments.

FIGS. 38A, 39A, 40A, 41A, 42A, 43A, 44A, 45A, and 46A are cross-sectional side views of various stages of manufacturing the semiconductor device structure taken along line D-D of FIG. 37, in accordance with some embodiments.

FIGS. 38B, 39B, 40B, 41B, 42B, 43B, 44B, 45B, and 46B are cross-sectional side views of various stages of manufacturing the semiconductor device structure taken along line E-E of FIG. 37, in accordance with some embodiments.

FIGS. 38C, 39C, 40C, 41C, 42C, 43C, 44C, 45C, and 46C are cross-sectional side views of various stages of manufacturing the semiconductor device structure taken along line F-F of FIG. 37, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As integrated circuit scales down, epitaxial critical dimension (EPI CD), which refers to spacings between epitaxial regions, becomes smaller and smaller. Small EPI CD makes it challenging to etch trenches for insulation structures without damaging adjacent structures, such as source/drain features. Exemplary insulation structures may include a Continuous Metal on Diffusion Edge (CMODE) structures or a Continuous-Poly-On-Diffusion-Edge (CPODE) structure. The CMODE or CPODE structures avoid leakage current through epitaxial source/drain features, transistors, and silicon substrates. In order to avoid photoresist peeling issue in a CMODE process or a CPODE process, the location of the cut pattern in the photoresist layer is purposely shifted away from a center axis of the gate structure. However, shifting the location of the cut pattern may cause bowing issue for the opening formed under the cut pattern between gate spacers of the gate structure. In addition, the source/drain features may be grown with a multilayer epitaxial process to enhance the etch resistance of source/drain features in the peripheral regime. Multilayer epitaxial process, however, may lead to formation of the voids in the source/drain features and therefore degradation of the performance of devices. The present disclosure solves the above-mentioned issues by employing a high selective sheet-cut process and a boron-based pre-treatment process to enable self-aligned CMODE or CPODE etch profiles. Embodiments of the present disclosure are applicable to any devices which may include CPODE or CMODE structures, such as planar FETs, Fin-FETs, Horizontal Gate All Around (HGAA) FETs, Vertical Gate All Around (VGAA) FETs, and other suitable devices.

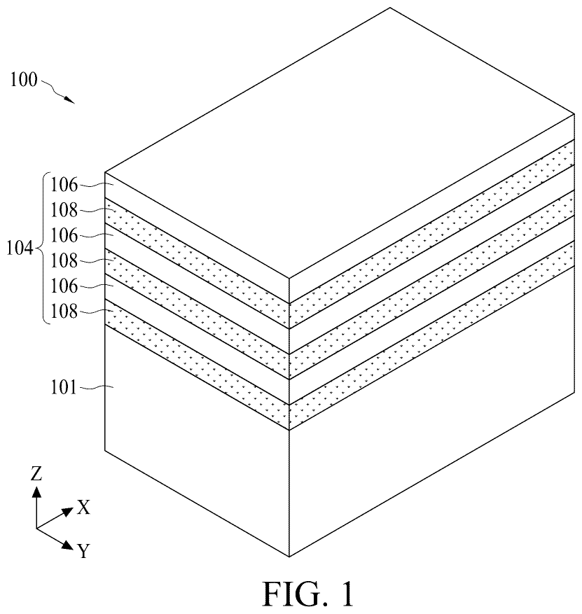

FIGS. 1 to 46C show exemplary processes for manufacturing a semiconductor device structure 100 according to embodiments of the present disclosure. It is understood that additional operations can be provided before, during, and after processes shown by FIGS. 1 to 46C, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-well region and boron for a p-well region.

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GalnP, GalnAsP, or any combinations thereof. In some embodiments, the second semiconductor layers 108 may be etched and replaced by other materials, such as SiO or SiN, during the processes.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

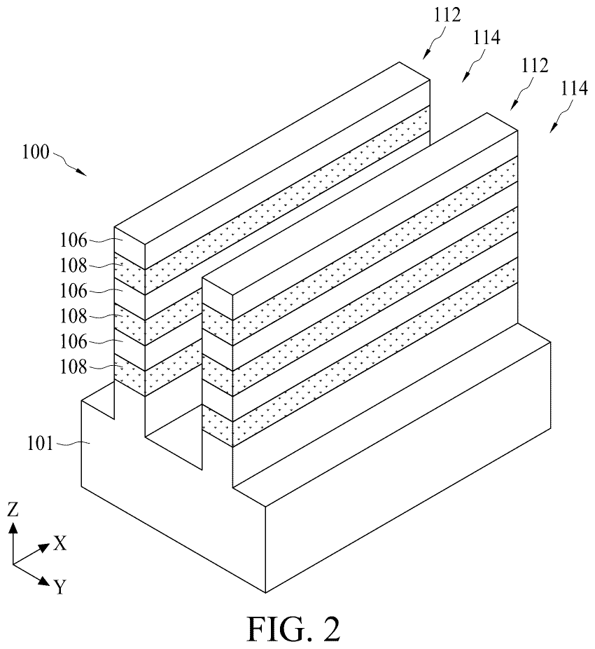

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking clement including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, each fin structure 112 has a longitudinal axis along the X direction.

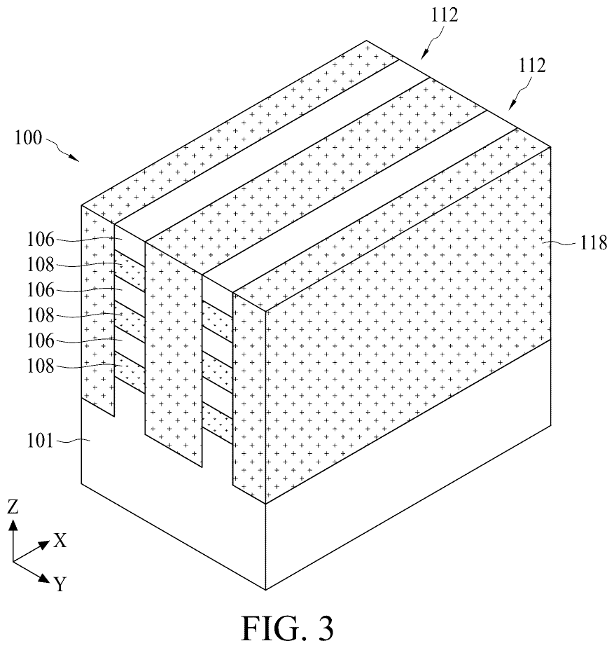

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be a multi-layer dielectric structure. The insulating material 118 may be formed by any suitable method, such as low-pressure chemical vapor deposition (LPCVD), plasma enhanced CVD (PECVD) or flowable CVD (FCVD).

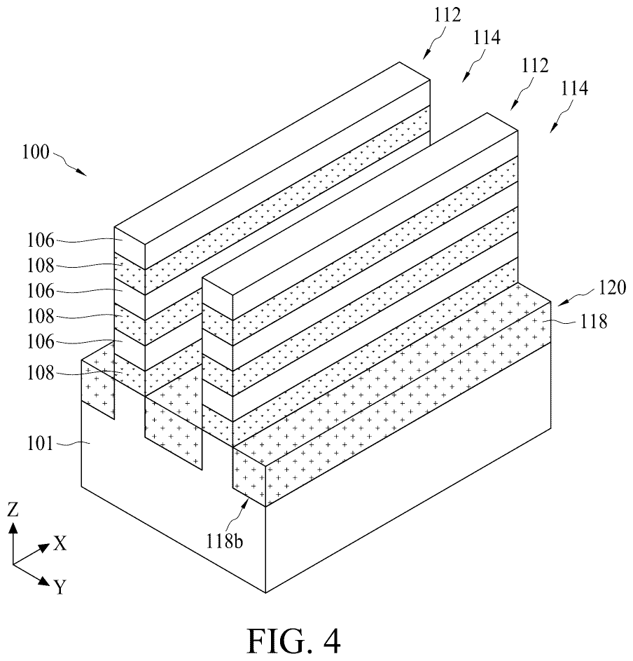

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

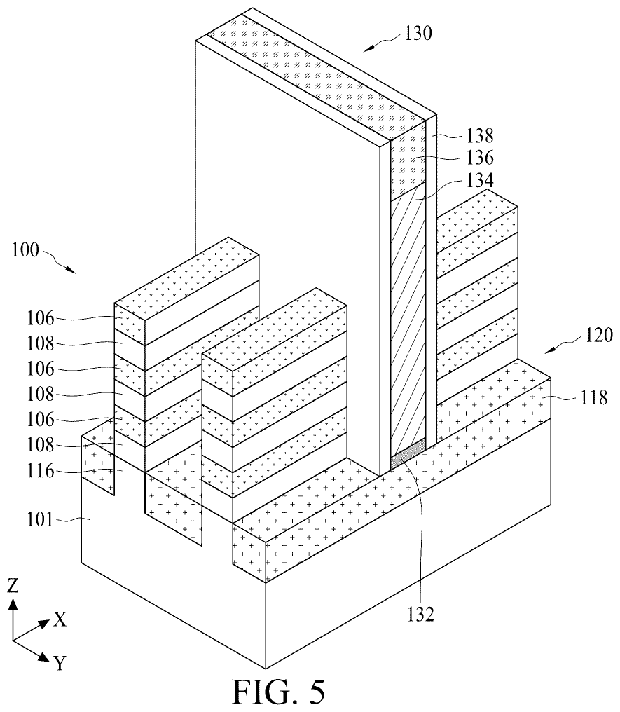

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on the sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

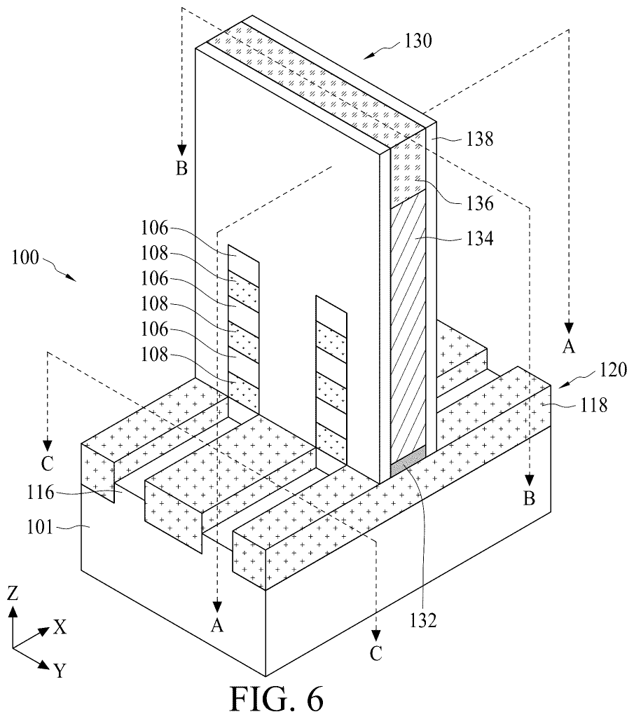

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

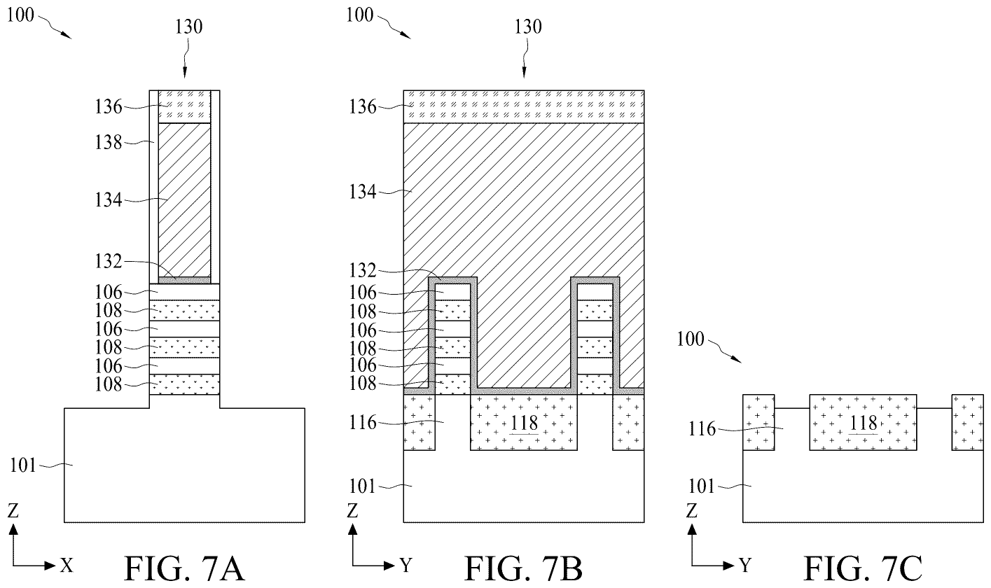

FIGS. 7A, 7B, and 7C are cross-sectional side views of the semiconductor device structure 100 taken along line A-A, line B-B, and line C-C of FIG. 6, respectively.

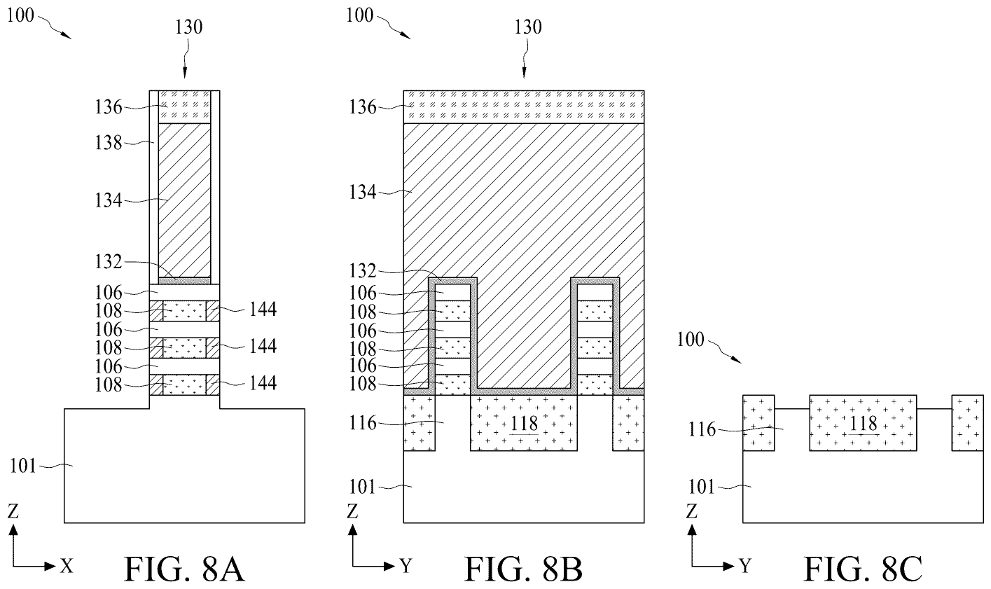

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

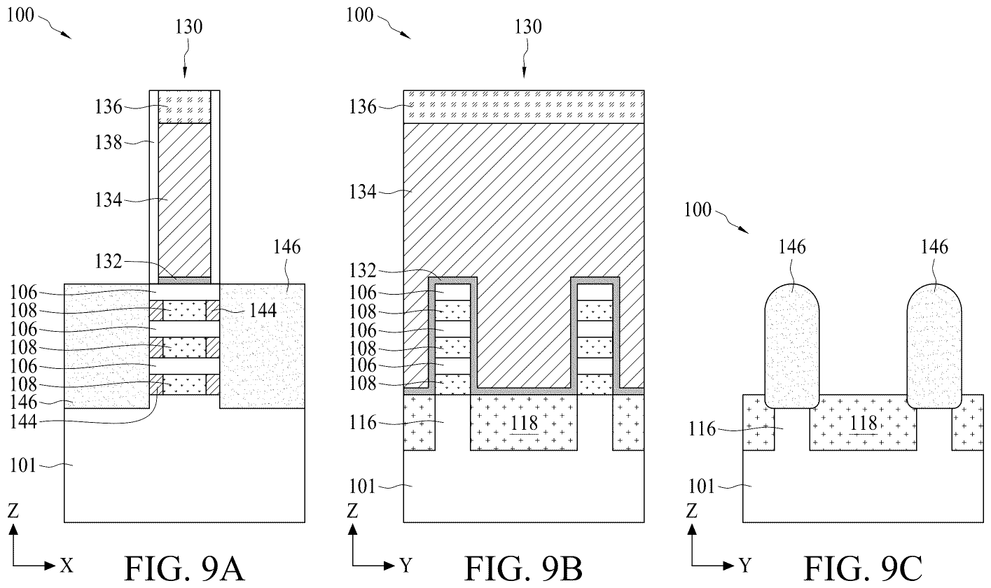

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) features 146 are formed from the first semiconductor layers 106 and the substrate portions 116. In some embodiments, the S/D features 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D features 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D features 146. The S/D features 146 may be formed by an epitaxial growth method using CVD, ALD or MBE.

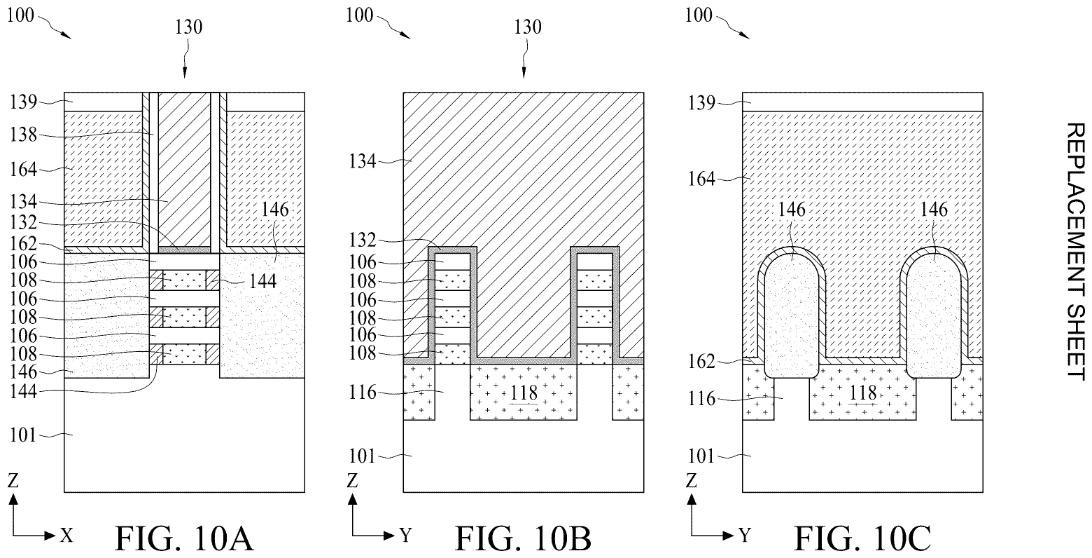

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D features 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164.

After the ILD layer 164 is formed, a planarization operation, such as CMP, is performed on the semiconductor device structure 100 until the sacrificial gate electrode layer 134 is exposed. In some embodiments, after the planarization process, the ILD layer 164 is recessed, and a cap layer 139 is formed on the recessed ILD layer 164. The cap layer 139 may include a nitride, such as silicon nitride, to protect the ILD layer 164 during subsequent processes. A second planarization process may be performed to remove portions of the cap layer 139 formed on the sacrificial gate electrode layer 134. After the planarization process, the top surfaces of the cap layer 139, the CESL 162, the gate spacers 138, and the sacrificial gate electrode layer 134 are substantially co-planar.

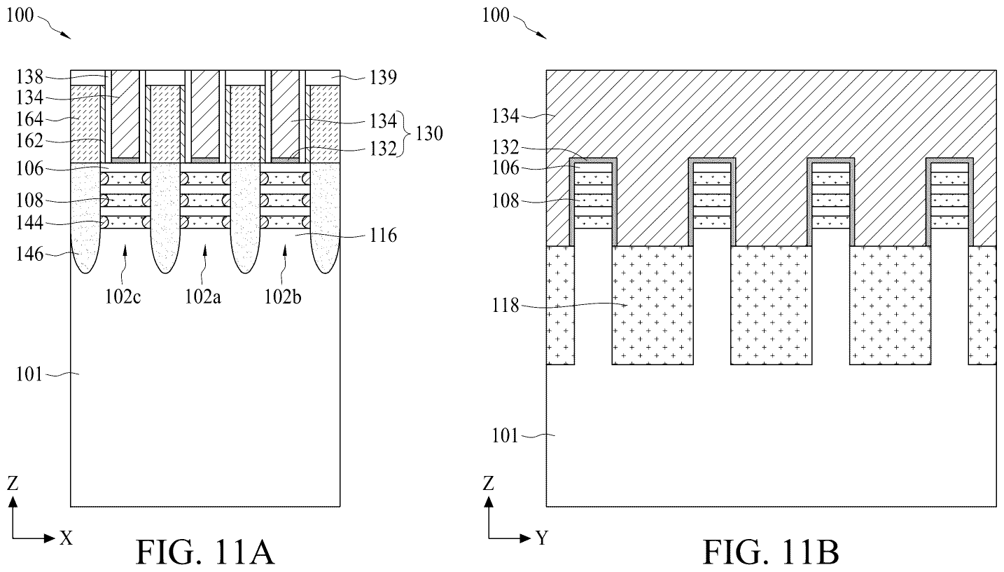

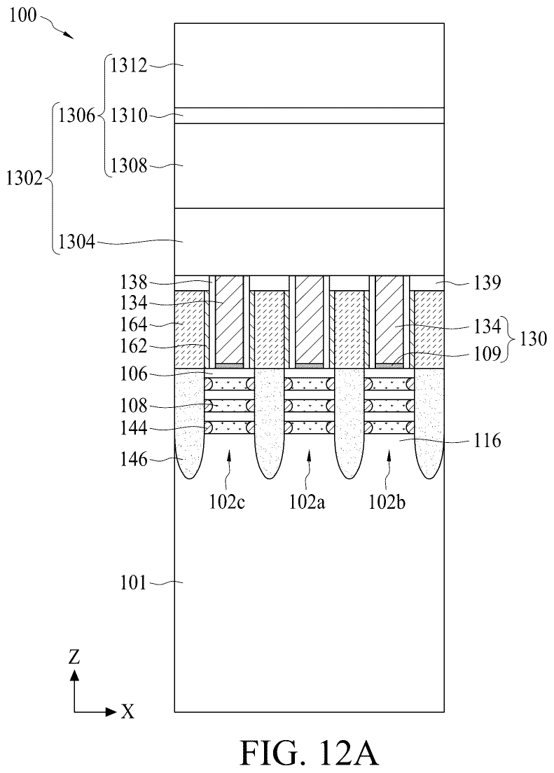

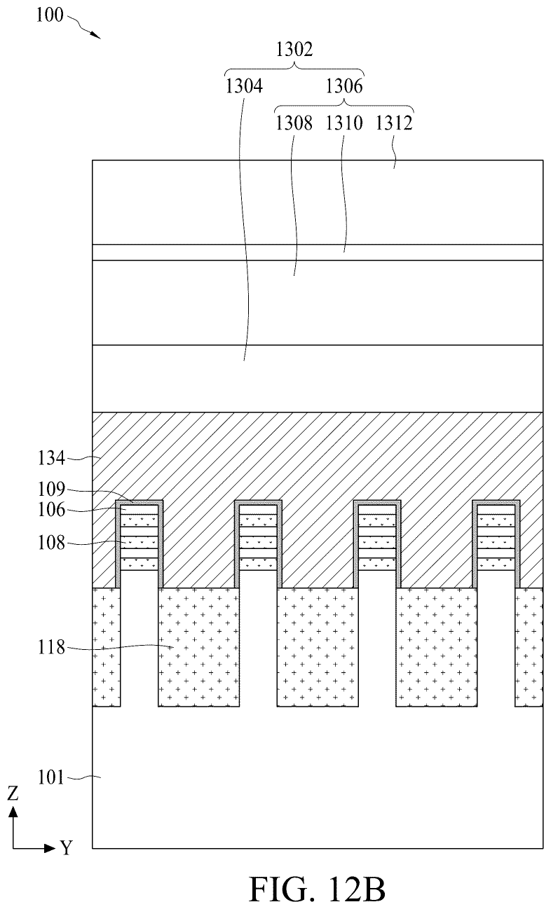

FIGS. 11A-11B to 18A-18B and 21A-21B to 25A-25B are cross-sectional side views of one of various stages of manufacturing the semiconductor device structure 100 of FIGS. 11A and 11B showing multiple fin structures disposed along the X and Y directions, respectively, in accordance with some exemplary embodiments. In FIGS. 12A and 12B, a mask structure 1302 is formed on the top surfaces of the sacrificial gate electrode layer 134, the gate spacers 138, the CESL 162, and the cap layer 139 (or the first ILD layer 164 if the cap layer 139 were not presented). The mask structure 1302 may include a hard mask 1304 and a resist layer 1306. The hard mask 1304 may be any suitable masking material. In some embodiments, the hard mask 1304 is formed of a nitrogen-containing material, such as a SiN or SiCN. The resist layer 1306 may be a single layer photoresist or a tri-layer photoresist. An exemplary tri-layer photoresist may include a bottom layer 1308, a middle layer 1310 disposed over the bottom layer 1308, and a photoresist top layer 1312 disposed over the middle layer 1310. The resist layer 1306 may be formed by any suitable process, such as a spin-on coating. The bottom layer 1308 may be a bottom anti-reflective coating (BARC) layer. The middle layer 1310 may be a silicon-containing inorganic polymer that provides anti-reflective properties and/or hard mask properties for a photolithography process. The photoresist top layer 1312 may be a DUV resist (KrF) resist, an argon fluoride (ArF) resist, an EUV resist, an electron beam (e-beam) resist, or an ion beam resist.

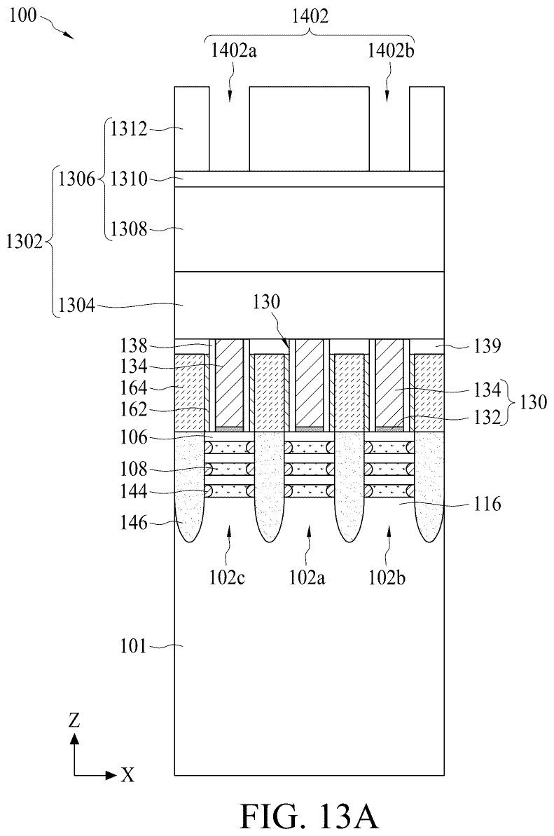

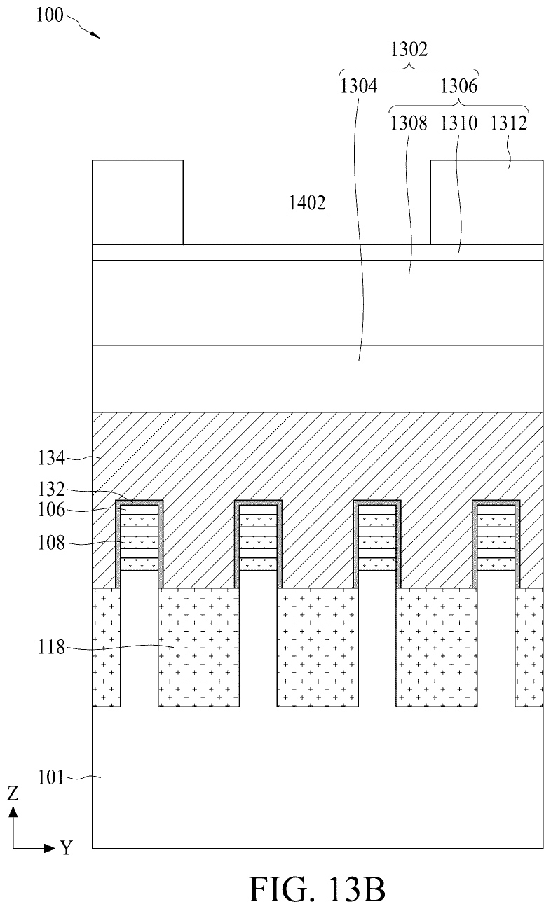

In FIGS. 13A and 13B, the photoresist top layer 1312 is patterned to form a plurality of photoresist mandrels separated from each other by an opening. For case of illustration, two opening 1402a, 1402b are shown. The patterned photoresist top layer 1312 is used as a mask to transfer the pattern (i.e., openings 1402a, 1402b) in the photoresist top layer 1312 into the middle layer 1310, the bottom layer 1308, and the mask layer 1304. The openings 1402a, 1402b define isolation trenches to be formed in the substrate portions of the fin structures 102b, 102c. The isolation trenches may be disposed between neighboring active regions. The term “active region” refers to a region where transistors are, or to be formed. As will be discussed in more detail below, the isolation trenches may be formed by performing a fin-cut (or sheet-cut) process. The isolation trenches are to be filled with a dielectric to form continuous poly on diffusion edge (CPODE) trenches. This fin-cut (or sheet-cut) process may be referred to a CPODE process. The term “diffusion edge” is equivalently referred to as an active edge, which is an edge abutting adjacent active regions. The CPODE process can be used to reduce gate pitch, thereby increasing the density for multi-gate devices and thus device performance required for aggressively scaled circuits and devices.

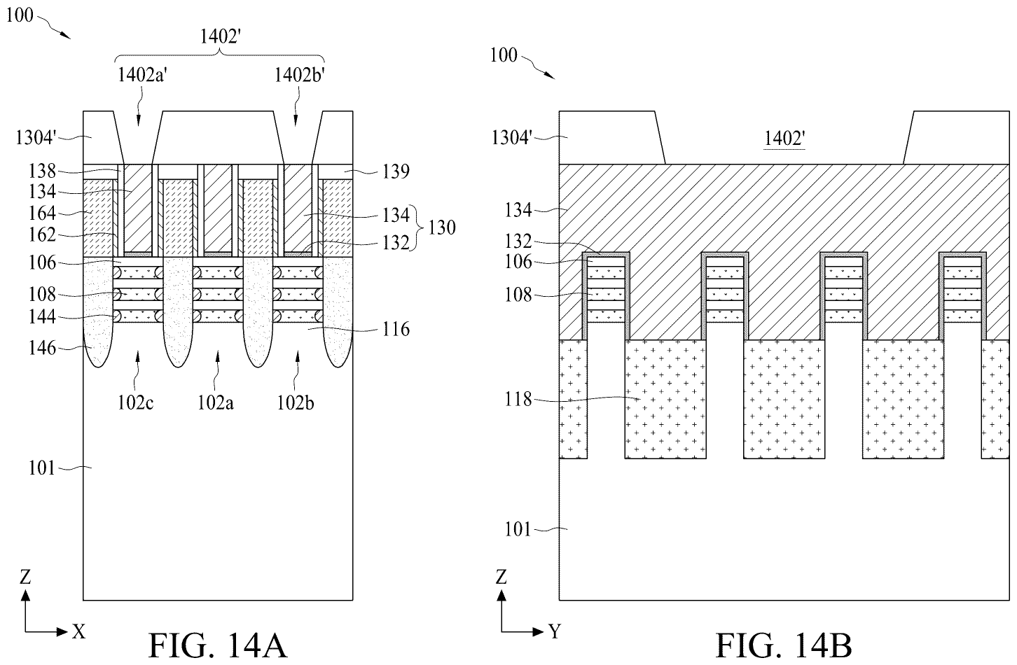

In FIGS. 14A and 14B, the patterns (i.e., openings 1402a, 1402b) in the photoresist top layer 1312 (FIGS. 13A and 13B) are transferred to the mask layer 1304 to form patterned mask layer 1304′. The bottom layer 1308, the middle layer 1310, the photoresist top layer 1312 are then removed. The formation of the patterned mask layer 1304′ may be achieved by one or more photolithographic processes. As a result of the one or more photolithographic processes, portions of the hard mask 1304 are removed, and trench patterns 1402a′, 1402b′ (collectively referred to as trench pattern 1402′) are formed in the patterned mask layer 1304′, and a portion of the sacrificial gate electrode layer 134 is exposed. The trench patterns 1402a′, 1402b′ are elongated openings in alignment with the sacrificial gate structures 130. The removal of portions of the hard mask 1304 (and native oxide formed thereon) may be performed using an etch chemistry, such as CF₄, CHF₃, CH₂F₂, CHF₃, C₄F₆, or the like or a combination thereof. The patterned mask layer 1304′ may then be used to protect active regions during subsequent removal of the exposed sacrificial gate structures and fin-cut (or sheet-cut) process.

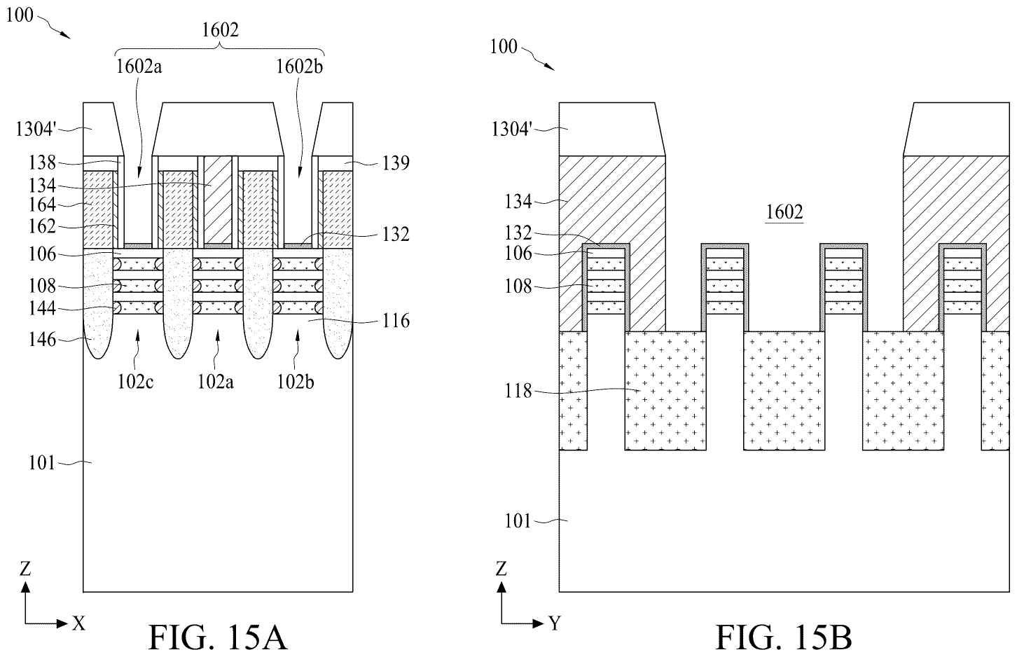

In FIGS. 15A and 15B, the exposed sacrificial gate structures (e.g., sacrificial gate electrode layer 134) are selectively removed to form openings 1602a, 1602b (collectively referred to as openings 1602). The openings 1602 expose the gate spacers 138 and the sacrificial gate dielectric layer 132. The removal of the exposed sacrificial gate structures may be performed by a selective etch process that removes the sacrificial gate electrode layer 134 but does not substantially affect the gate spacers 138 and the sacrificial gate dielectric layer 132. The sacrificial gate dielectric layer 132 protects the first and second semiconductor layers 106, 108 during the etch back process. In some embodiments, the sacrificial gate dielectric layer 132 may also be removed during the selective etch process. In some embodiments, an etch chemistry selective to the sacrificial gate structures to be etched is used. The etch chemistry is chosen so that etching of the surrounding dielectric layers, such as the insulating material 118, the gate spacers 138, the CESL 162, and the first ILD layer 164, is minimized. In some embodiments, the sacrificial gate structures 130 may be removed using chlorine containing gases, such as SiCl₄, BCl₃, Cl₂, CHCl₃, CCl₄, and/or BCl₃, bromine-containing gas, such as HBr and/or CHBr₃, iodine-containing gas, other suitable gases and/or plasmas, and/or combinations thereof. In some embodiments, the sacrificial gate electrode layer 134 has a top that is flush with the top of the sacrificial gate dielectric layer 132. The subsequent fin-cut or sheet-cut process will remove the sacrificial gate electrode layer 134 and the sacrificial gate dielectric layer 132 in the CPODE trench.

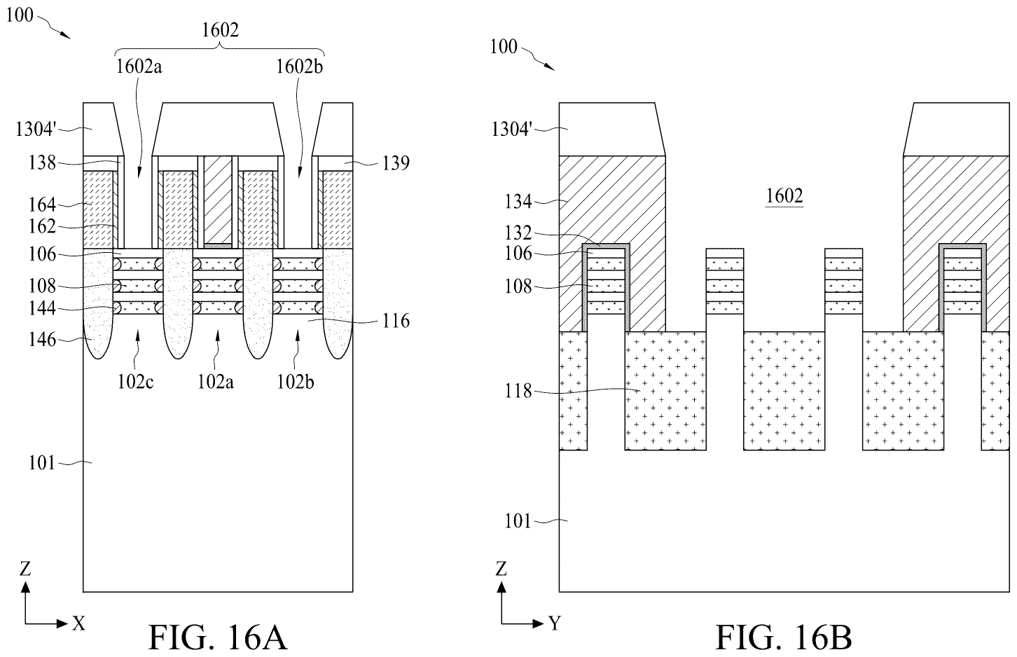

In FIGS. 16A and 16B, an etch process is performed to remove the sacrificial gate dielectric layer 132. The etch process may be a dry etch, a wet etch, or a combination thereof. The etch process selectively removes the sacrificial gate dielectric layer 132 without affecting the first and second semiconductor layers 106, 108, as well as the sacrificial gate electrode layer 134.

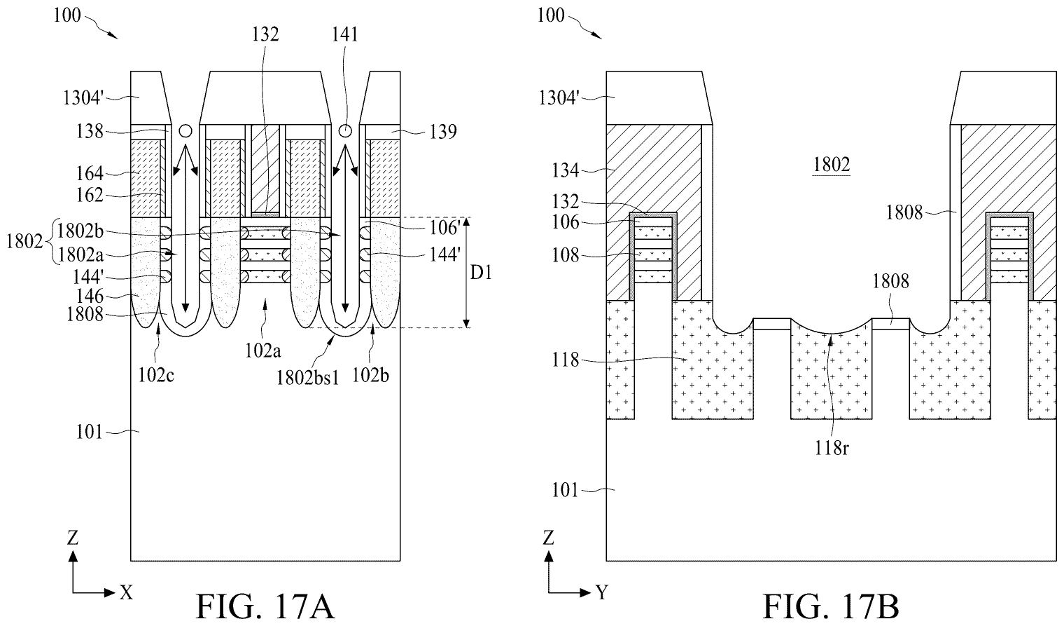

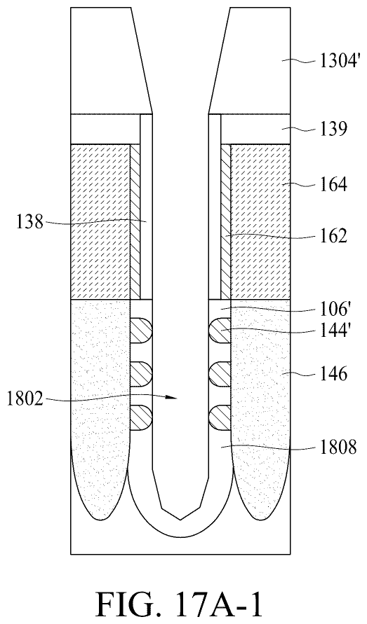

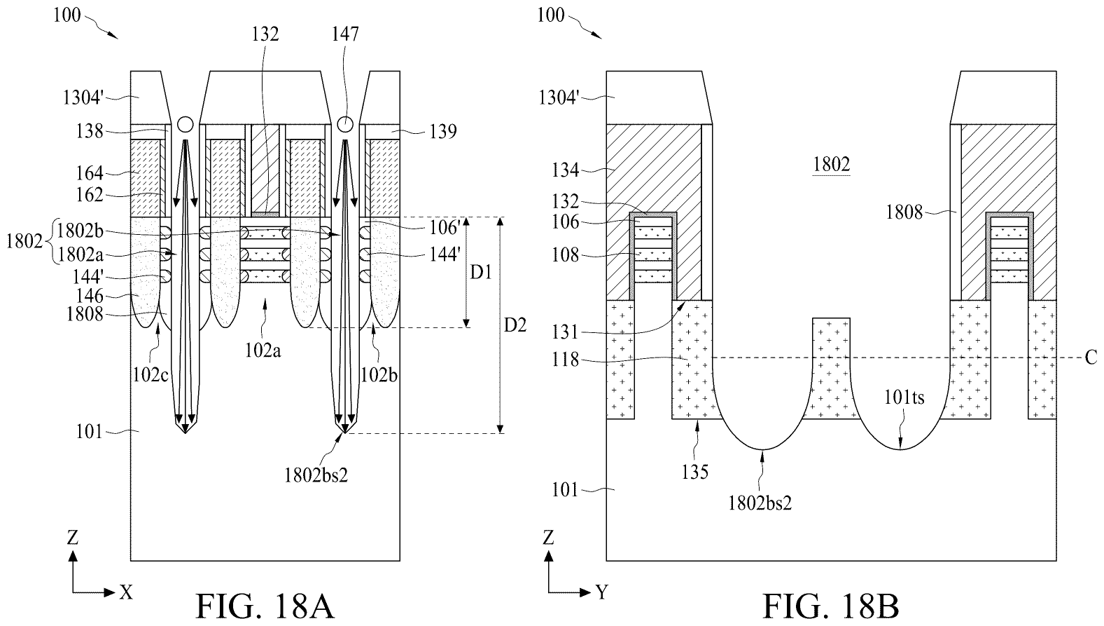

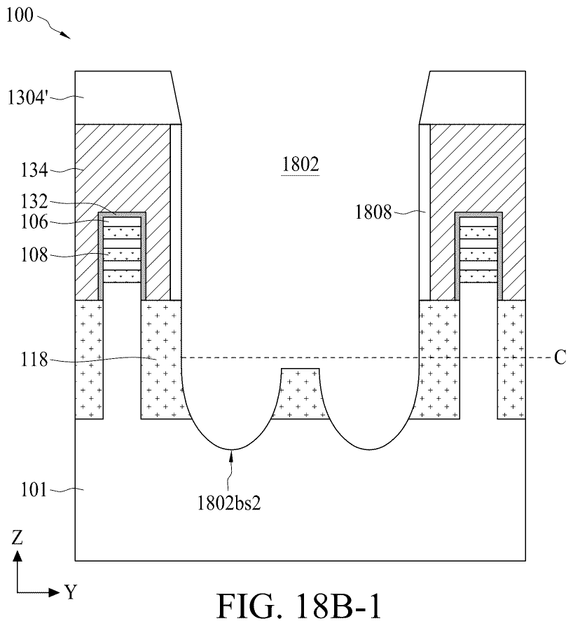

FIGS. 17A and 17B to 18A and 18B illustrate processes of employing plasma doping of impurities and extending the openings 1602 into substrate portions of fin structures 102b, 102c for forming isolation trenches. In FIGS. 17A and 17B, a first semiconductor etch process 141 is performed to remove the first and second semiconductor layers 106, 108 (and in some cases, a small portion of the exposed insulating material 118 due to bombardment of ions), thereby forming a first section of the isolation trenches 1802. The first semiconductor etch process 141 is a fin-cut (or sheet-cut) process. The first semiconductor etch process 141 is performed using the patterned mask layer 1304′ as an etching mask, and the etch process may continue until a bottom 1802bs1 of the isolation trenches 1802 reaches substantially the same elevation as the bottom of the S/D features 146.

In various embodiments, the first semiconductor etch process 141 further includes a treatment process. The treatment process can be a doping process so that impurities (e.g., Group III elements) are simultaneously or consecutively doped into a surface (e.g., sidewalls) of the isolation trenches 1802. The doped regions form a protection barrier 1808 in the sidewalls of the isolation trenches 1802. The sidewalls of the isolation trenches 1802 include the doped first semiconductor layers 106′ and doped dielectric spacers 144′. Therefore, surface portions of the doped first semiconductor layers 106′ and the doped dielectric spacers 144′ serve as the protection barrier 1808. The doping of impurities enhances etch resistance of the S/D features 146 during the subsequent etch process, enabling damage-free, simple epitaxy structures of the S/D features 146 even if the lithography mask overlay shift happens. The etch resistance of the S/D features 146 can be increased because Group III elements (trivalent) all contain three valence electrons and function as acceptors when used to dope silicon. When an acceptor atom replaces a tetravalent silicon atom in the crystal, a vacant state (an electron-hole) is created. The plasma doping of Group III elements increases the electron-hole concentration in the surface (e.g., sidewalls) of the isolation trenches 1802. It has been observed that the high electron-hole concentrations in the doped region can lead to etch rate reduction in the doped region, allowing the doped regions to serve as a protection barrier for the isolation trenches 1802. As a result, the etch resistance of the S/D features 146 is increased and the integrity of the S/D features 146 can remain substantially intact during the subsequent etch process.

The first semiconductor etch process 141 may be dry etch, reactive ion etch (RIE), and/or other suitable processes. In some embodiments, the first semiconductor etch process 141 is an anisotropic etch (directional etch) process. The first semiconductor etch process 141 is performed so that the exposed first semiconductor layers 106, the second semiconductor layers 108, and portions of the substrate 101 forming the fin structures 102b, 102c are selectively removed. A portion of the insulating material 118 around the fin structures 102b, 102c may also be removed. In some embodiments, the removal of the exposed first semiconductor layers 106, the second semiconductor layers 108, and portions of the substrate 101 is achieved using a self-aligned CPODE etch process. The self-aligned CPODE etch process is configured to have high etch selectivity so that the etch rate of the first and second semiconductor layers 106, 108 is greater than the etch rate of the dielectric spacers 144. As a result, the dielectric spacers 144 remain substantially intact after the fin-cut process.

In various embodiments, the self-aligned CPODE etch process is a plasma etch using etchants containing reactive elements selected from the halogen group, such as bromine, chlorine, fluorine, etc. For example, the etchants may use a bromine-based etch chemistry, a chlorine-based etch chemistry, a fluorine-based etch chemistry, or the like, or any combination thereof. In some embodiments, a hydrocarbon-based etch chemistry is used. Other active gases, such as oxygen-based etch chemistry, may also be used in conjunction with the etchants to facilitate dissociation of the plasma by product. During the plasma etch, a treatment process employing impurities of Group III elements (i.e., P-type dopants), such as a boron, aluminum, gallium, and/or indium, is performed to dope the surface (e.g., sidewalls) of the isolation trenches 1802 with Group III elements. The treatment process may be any suitable doping process, such as a plasma doping process or an implantation process. The treatment process may be performed concurrently or intermittently with the plasma etch. In cases where the treatment process is performed concurrently with the plasma etch, the dopant gas may flow concurrently with the etchants. In cases where the treatment process is performed intermittently with the plasma etch, the dopant gas and the etchants may be provided sequentially in a cyclic fashion until the desired depth of the isolation trenches 1802 is reached. In either case, the temperature of the plasma etch is controlled so that the P-type dopants may not be activated. In addition, the P-type dopants are confined in the surface regime to avoid impacting the electrical properties of the devices. In any case, the P-type dopants in the doped regions form a protection barrier 1808 for the isolation trenches 1802. In some embodiments, the plasma etch and the treatment process are performed until the insulating material 118 is exposed. In such cases, the top surface of the insulating material 118 may have a recess 118r with a curved or concave profile.

Exemplary hydrocarbon-based etch chemistry may include methane (CH₄), ethane (C₂H₆), propane (C₃H₈), or the like, or a combination thereof. Exemplary bromine-based etch chemistry may include, but are not limited to, hydrogen bromide (HBr), bromine (Br₂), boron tribromide (BBr₃), or the like, or a combination thereof. Exemplary chlorine-based etch chemistry may include, but are not limited to, chlorine gas (Cl₂), chloroform (CHCl₃), carbon tetrachloride (CCl₄), boron trichloride (BCl₃), or the like, or a combination thereof. Exemplary fluorine-containing gas may include, but is not limited to, tetrafluoromethane (CF₄), hexafluorocthane (C₂F₆), octofluorocyclobutane (C₄F₈), hexafluorobutadiene (C₄F₆), sulfur hexafluoride (SF₆), nitrogen trifluoride (NF₃). difluoromethane (CH₂F₂), difluoroethane (C₂H₄F₂), trifluoromethane (CHF₃), hexafluoroethane (C₂F₆), or the like, or a combination thereof. Exemplary oxygen-based etch chemistry may include, but are not limited to, oxygen gas (O₂), carbon dioxide (CO₂), ozone (O₃), water vapor, or the like, or a combination thereof. Exemplary dopant gas for the treatment process may include, but is not limited to, a boron-containing gas such as diborane (B₂H₆), boron trichloride (BCl₃), borane (BH₃), boron tribromide (BBr₃), boron trifluoride (BF₃), tricthyl borate (TEB), borazine (B₃N₃H₆), or an alkyl-substituted derivative of borazine, or the like, or a combination thereof. A dilute gas, such as helium (He), nitrogen (N₂), or the like, may also be used in combination with the etch chemistries and/or the dopant gas. An inert gas, such as argon (Ar), neon (Ne), krypton (Kr), or the like, may be provided with the etch chemistries to increase bombardment effect and thus, enhanced etch rates of the first and second semiconductor layers 106, 108.

An exemplary plasma etch may include exposing the semiconductor device structure 100 to a gas mixture comprising one or more etch chemistries in a high density plasma process chamber using an ICP (inductive coupled plasma) or dipole antenna plasma source. In some embodiments, resonant antenna plasma source or electron cyclotron resonance (ECR) plasma source may also be used to enable low pressure operation (e.g., about 0.2±0.05 mTorr). The plasma etch process may use a plasma formed from a gas mixture comprising HBr and BCl₃. In some embodiments, the plasma etch process uses a plasma formed from a gas mixture comprising CH₄, BCl₃, HBr, CHF₃, for example. The plasma may be driven by an RF power generator using an AC electrical current operating on a frequency of multiple of 13.56 MHz. The process chamber may be operated at a pressure in a range of about 0.2 mTorr to about 150 mTorr and a temperature of about 20 degrees Celsius to about 120 degrees Celsius. The RF power generator is operated to provide source power between about 100 W to about 2500 W. Higher directionality can be achieved by adding a bias power to a substrate pedestal in the process chamber. In such cases, a DC bias power operating in a range of about 0 V to about 1000 V (e.g., about 50V-150 V) may be used. The source power and the bias power may be controlled so that the ion acceleration energy is between about 20 eV to about 200 cV. In some cases, a pulse plasma etch may be used. In such cases, the output of the power generator may be controlled by a pulse signal having a duty cycle in a range of about 5% to 95%. Alternatively, the self-aligned CPODE etch process may use a bias power only (with zero source power) to enhance etch directionality.

An exemplary plasma doping process may include exposing the semiconductor device structure 100 to a plasma generated from one or more dopant gases (e.g., a boron-containing gas such as B₂H₆ or BCl₃) and the dilute gas in a plasma doping chamber. The plasma doping process may be performed at a constant energy of between about 2 keV and about 5 keV, a bias voltage of about −200V to about −20 kV, and a chamber pressure of about 1 mTorr to about 50 mTorr, to dope plasma ions (e.g., boron) into the surface (e.g., sidewalls) of the isolation trenches 1802. After the plasma doping process, the doped region (e.g., the protection barrier 1808) may have a dopant concentration of boron in a range from about 1.0E15 atoms/cm³ to about 3.0E22 atoms/cm³. The plasma doping process can form an abrupt doping profile junction at a depth of about 5 nm to about 10 nm from surfaces of the isolation trenches 1802 with a doping profile abruptness of about 1 nm/decade.

As a result of the first semiconductor etch process 141, isolation trenches 1802a, 1802b (collectively referred to as isolation trenches 1802) are formed and extended into portions of the substrate 101 forming the fin structures 102b, 102c (FIG. 17A). The impurities of dopants (Group III elements), such as boron, form a thin doped region in the surface (e.g., sidewalls) of the isolation trenches 1802, which includes the doped first semiconductor layers 106′ and the doped dielectric spacers 144′. In some embodiments, the thin doped region (i.e., protection barrier 1808) may be amorphous. In various embodiments, the first semiconductor etch process 141 is performed such that the first section of the isolation trenches 1802a, 1802b are formed with a straight and symmetric sidewall profile with respect to an imaginary line passing through a center of the respective isolation trenches 1802a, 1802b in the depth direction of the isolation trenches 1802a, 1802b. In some embodiments, the isolation trenches 1802a, 1802b may have a first depth D1, which is defined by a distance between the topmost first semiconductor layer 106 and a bottom surface 1802bs1 of the isolation trenches 1802a, 1802b. The first depth DI may be selected according to desirable level of the narrowest critical dimension (CD). In some embodiments, the bottom surface 1802bs1 of the isolation trenches 1802a, 1802b is at substantially the same elevation as the bottom of the epitaxial S/D features 146. In some embodiments, the bottom surface 1802bs1 of the isolation trenches 1802a, 1802b is below a top surface of the well portion of the substrate 101. In some embodiments, the first depth DI is substantially equal to the height of the epitaxial S/D features.

FIG. 17A-1 illustrates an enlarged view of a portion of the semiconductor device structure 100 showing the protection barrier 1808 in the sidewalls of the isolation trenches 1802. In cases where the dopant gas containing Group III dopants (e.g., boron), a portion of the doped first semiconductor layers 106′ may have a first concentration of boron, and a portion of the doped dielectric spacers 144′ may have a second concentration of boron that is lower than the first concentration of boron. The gate spacers 138 may have a third concentration of boron that is lower than the second concentration of boron. In some cases, the third concentration of boron is nearly zero. This is because the dopant gas (e.g., BCl₃) can react with oxides (e.g., gate spacers 138) to form volatile by-products (e.g., boron oxychlorides), resulting in low or substantially zero concentration of boron in the gate spacers 138. The boron concentration may gradually decrease in the protection barrier 1808 in the direction away from the surface of the isolation trenches 1802. In some embodiments, the boron dopants may travel a first distance in the first semiconductor layers 106, and the boron dopants may travel a second distance in the dielectric spacers 144 that is shorter than the first distance. In any case, the boron dopants may not penetrate an interface 133 defined by the first semiconductor layer 106 and the S/D features 146. It should be noted that such a doping phenomenon is applicable to other Group III dopants.

In FIGS. 18A and 18B, a second semiconductor etch process 147 is performed to further remove the exposed insulating material 118 and the substrate portion forming the fin structure 102b, 102c. Likewise, the second semiconductor etch process 147 is performed such that a second section of the isolation trenches 1802a, 1802b are formed with a straight and symmetric sidewall profile with respect to an imaginary line passing through a center of the respective isolation trenches 1802a, 1802b in the depth direction of the isolation trenches 1802a, 1802b. The isolation trenches 1802 are formed with a uniform CD along the depth direction. Particularly, the second semiconductor etch process 147 is performed such that the bottom of the isolation trench 1802, or stated differently, a top surface 101ts of the exposed substrate 101, is below an interface 135 defined by the substrate 101 and the insulating material 118.

The second semiconductor etch process 147 is performed using an etch chemistry similar to the first semiconductor etch process 141. In some embodiments, the treatment process discussed above is not performed during the second semiconductor etch process 147. In some embodiments, the treatment is performed concurrently or intermittently with the second semiconductor etch process 147, in a similar fashion as discussed above. The substrate portion of the fin structure 101b, 102c may be removed by the second semiconductor etch process 147 using a plasma etch process comprising HBr and/or Cl₂. In some embodiments, O₂ and/or CO₂ may be added to HBr and/or Cl₂ based plasma to facilitate dissociation of the plasma by product. In some embodiments, the plasma etch process may be a high density plasma process using process conditions similar to the first semiconductor etch process 141. The second semiconductor etch process 147 is performed to extend the isolation trenches 1802a, 1802b to an elevation substantially equal to an interface 135 defined by the substrate 101 and the insulating material 118. The isolation trenches 1802a, 1802b have a second depth D2 measuring from the topmost first semiconductor layer 106 to a bottom surface 1802bs2 of the isolation trenches 1802a, 1802b. In other words, the depth of each isolation trench 1802a, 1802b is extended from the first depth D1 to the second depth D2. The isolation trenches 1802 with homogeneous CD along the depth direction can be obtained through a cyclic process. For example, the processes in FIGS. 17A and 17B to 18A and 18B may repeat until the isolation trenches 1802a, 1802b reach a predetermined height (or depth).

One or more etch conditions may be controlled to achieve low selectivity etching between silicon (e.g., substrate 101) and silicon oxide (e.g., insulating material 118). For example, a low-pressure process (e.g., chamber pressure below about 50 mTorr) and/or high bias power to the substrate pedestal (e.g., greater than 300 V) may be utilized during the second semiconductor etch process 147 to compensate for etch selectivity needed for removing the insulating material 118 and the substrate portion of the fin structures 102b, 102c. In some embodiments, the bias power used during the second semiconductor etch process 147 is greater than that of the first semiconductor etch process 141.

In some embodiments, an etchant (e.g., Cl₂ or BCl₃) that removes both target material (e.g., silicon) and non-target material (e.g., silicon oxide) may be used to achieve or enhance low etching selectivity of the second semiconductor etch process 147. In some embodiments, the mixing ratio between the gases used in the second semiconductor etch process 147 is adjusted to achieve the low etching selectivity. For example, in embodiments where BCl₃ is used as the etchant, increasing the volume percentage of BCl₃ in the etchant may decrease the etching selectivity. In some embodiments, the etchant may be a mixture of HBr, BCl₃, Cl₂, and O₂, where a percentage (e.g., volume percentage) of HBr in the etchant is between 0% and about 80%, a percentage of BCl₃ in the etchant is between about 5% and about 80%, a percentage of Cl₂ in the etchant is between 0% and about 80%, and a percentage of O₂ in the etchant is between 0% and about 50%.

The low etching selectivity of the second semiconductor etch process 147 ensures that the isolation trenches 1802 has a liner sidewall profile, and there is no “bowing” in the isolation trenches 1802. Bowing may occur when the width of a section of the isolation trenches is larger than the widths of adjacent sections of the isolation trenches.

In any case, the bottom surface 1802bs2 of the isolation trenches 1802a, 1802b may be at an elevation within an accumulation region of the substrate 101. The term “accumulation region” refers to a non-conductive region in the substrate 101, which is below a depletion region (a conductive region located at/near the well region of the substrate 101). The second depth D2 is sufficient to block the path of leakage current through epitaxial source/drain features and the silicon substrate. In some embodiments, the second depth D2 may be in a range between about 60 nm and about 200 nm.

In some embodiments, the second semiconductor etch process 147 is performed such that the bottom surface of the isolation trenches 1802 is at an elevation below the interface 135 defined by the substrate 101 and the insulating material 118. For example, the bottom surface may be at an elevation within the well region of the substrate 101. In cases where the treatment process is not used during the second semiconductor etch process 147, the fin structures exposed through the isolation trenches 1802 and a portion of the insulating material 118 surrounding the fin structures are removed, leaving the majority of the insulating material 118 between the two adjacent fin structures substantially intact. In such cases, the top of the insulating material 118 between two adjacent isolation trenches 1802 is slightly below an interface 131 defined by the insulating material 118 and the sacrificial gate electrode layer 134 (or the sacrificial gate dielectric layer 132), but above the halfway point of the height of the insulating material 118. As shown in FIG. 18B, the top of the insulating material 118 is above a center line “C” extending laterally through the halfway point of the height of the insulating material 118.

In cases where the treatment is performed concurrently or intermittently with the second semiconductor etch process 147, the fin structures exposed through the isolation trenches 1802 and a portion of the insulating material 118 surrounding the fin structures are greatly removed, resulting in the insulating material 118 between the two adjacent fin structures with a top below the halfway point of the height of the insulating material 118, as shown in FIG. 18B-1. In some cases, the top of the insulating material 118 is below a center line “C” extending laterally through the halfway point of the height of the insulating material 118, and the top of the remaining insulating material 118 may have a tapering profile, as shown in FIG. 18B-2.

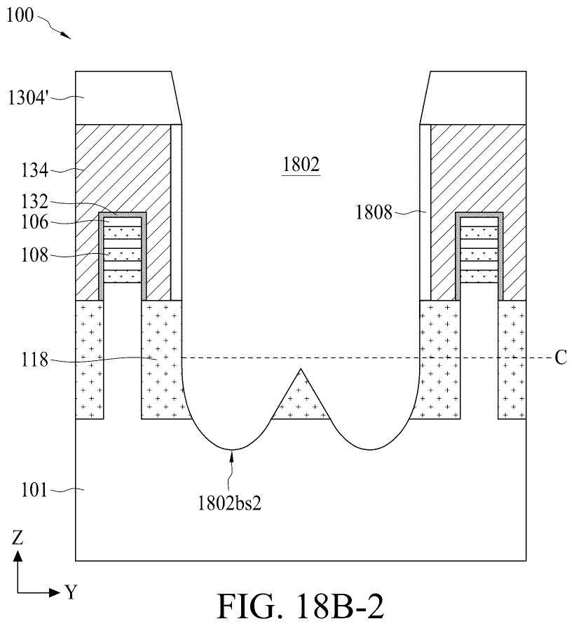

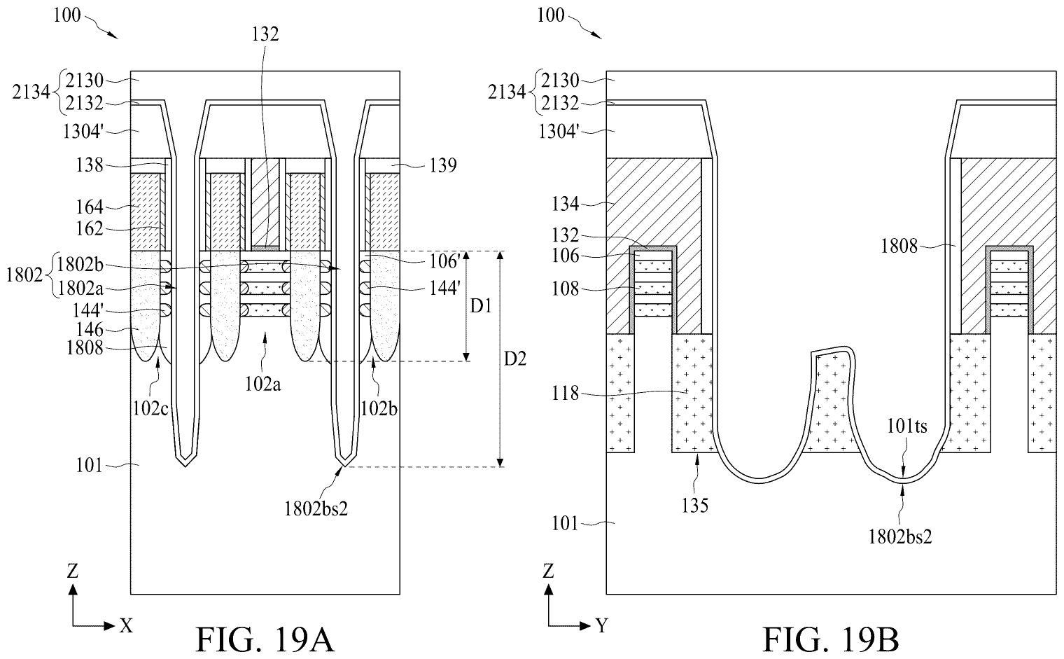

In FIGS. 19A and 19B, the isolation trenches 1802 (FIGS. 18A and 18B) are filled with a dielectric material 2130. In some embodiments, a dielectric liner 2132 may be disposed between the dielectric material 2130 and the exposed surfaces of the isolation trenches 1802. The dielectric material 2130 and the dielectric liner 2132 filled within the isolation trenches 1802 form isolation trench structures (so-called CPODE trenches) 2134. The protection barrier 1808 is disposed between and in contact with the isolation trench structures 2134 and the S/D features 146. The dielectric material 2130 and the dielectric liner 2132 may be made of an oxygen-containing material, such as silicon oxide (SiO₂); a nitrogen-containing material, such as silicon nitride, silicon oxynitride (SiON), SiOCN, SiCN; a low-K dielectric material; or any suitable dielectric material. The dielectric material 2130 may include a material chemically different than the and the dielectric liner 2132, and may be formed by any suitable process, such as a CVD, PECVD, FCVD, or ALD process.

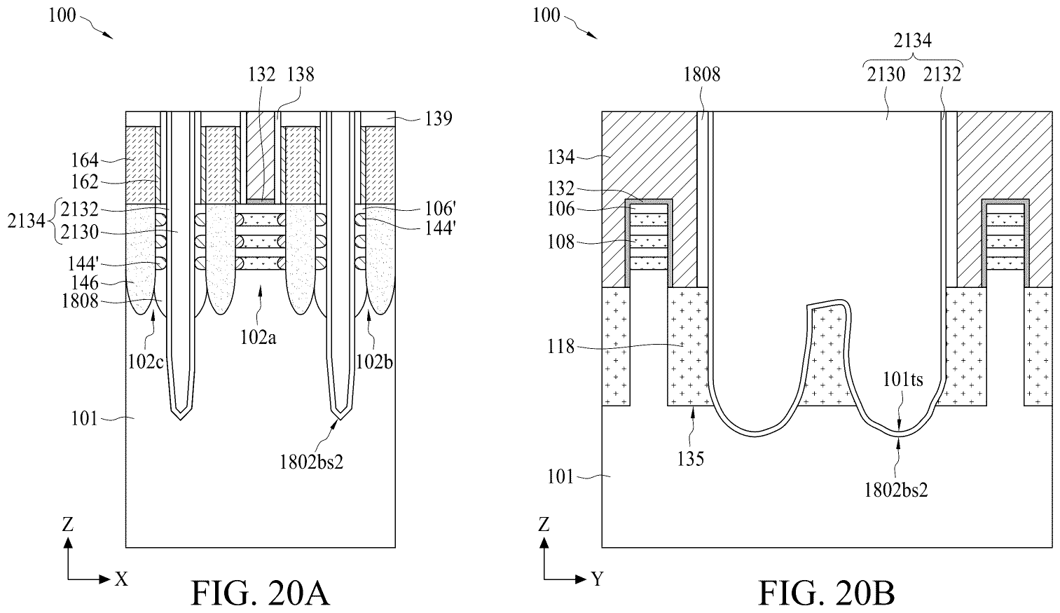

In FIGS. 20A and 20B, once the isolation trenches 1802 are filled, a planarization process, such as a CMP process, may be performed. The planarization process may be performed until a portion of the cap layer 139 or the ILD layer 164 is exposed.

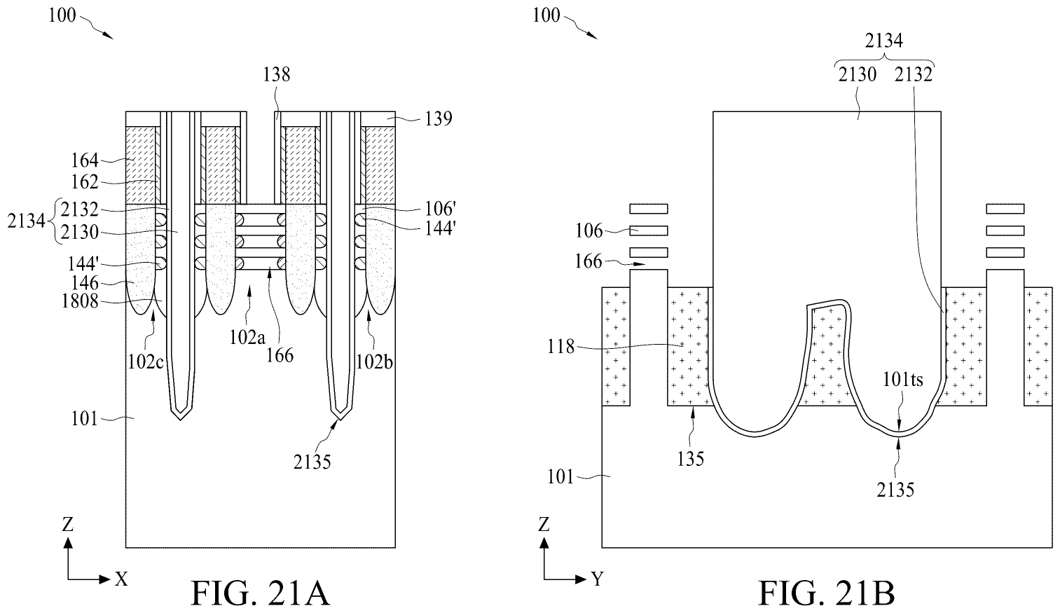

In FIGS. 21A and 21B, the sacrificial gate structures 130, the sacrificial gate dielectric layer 132, and the second semiconductor layers 108 are removed. The exposed dielectric liner 2132 on the sidewalls of the dielectric material 2130 may also be removed. The removal of the sacrificial gate structures 130 and the semiconductor layers 108 forms an opening 166 between the first semiconductor layers 106. The cap layer 139, the CESL 162, the first ILD layer 164, and the protection barrier 1808 protect the S/D features 146 during the removal processes. The sacrificial gate structures 130 can be removed using plasma dry etching and/or wet etching. In some embodiments, a wet etchant such as a tetramethylammonium hydroxide (TMAH) solution can be used to selectively remove the sacrificial gate electrode layer 134 and the sacrificial gate dielectric layer 132 but not the gate spacers 138, the isolation trench structures 2134, the first ILD layer 164, and the CESL 162. After the removal of the sacrificial gate structures 130, the first semiconductor layers 106 and the dielectric spacers 144 are exposed to the opening 166.

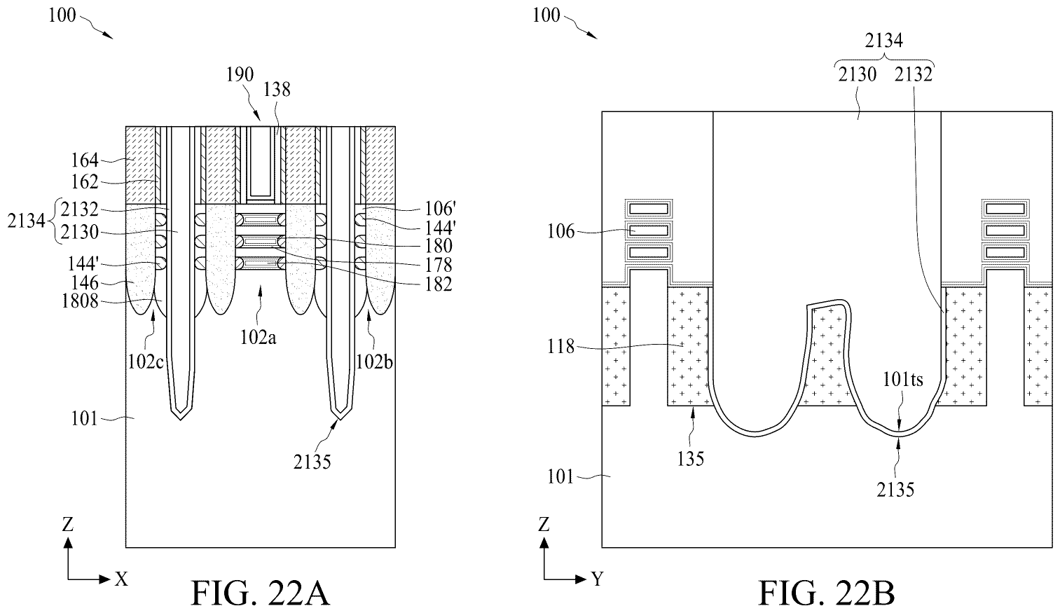

In FIGS. 22A and 22B, replacement gate structures 190 are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178 may also form on the exposed surfaces of the substrate 101, the insulating material 118, and the dielectric layer 2132. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the first ILD layer 164, the CESL 162, and the cap layer 139). The gate dielectric layer 180 may be formed of a material chemically different than that of the sacrificial gate dielectric layer 132. The gate dielectric layer 180 may include or made of a high-k dielectric material. The gate dielectric layer 180 may be a conformal layer formed by a conformal process, such as an ALD process, a PECVD process, a molecular-beam deposition (MBD) process, or the like, or a combination thereof.

After formation of the IL (if any) and the gate dielectric layer 180, the gate electrode layer 182 is formed on the gate dielectric layer 180. The gate electrode layer 182 filles the openings 166 (FIG. 21A) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the first ILD layer 164, the CESL 162, the cap layer 139 (if any), and the gate spacers 138 may be removed by a planarization process, such as by a CMP process. After the CMP process, the top surfaces of the isolation trench structure 2134, the first ILD layer 164, the CESL 162, the gate spacers 138, and the gate electrode layer 182 are substantially co-planar.

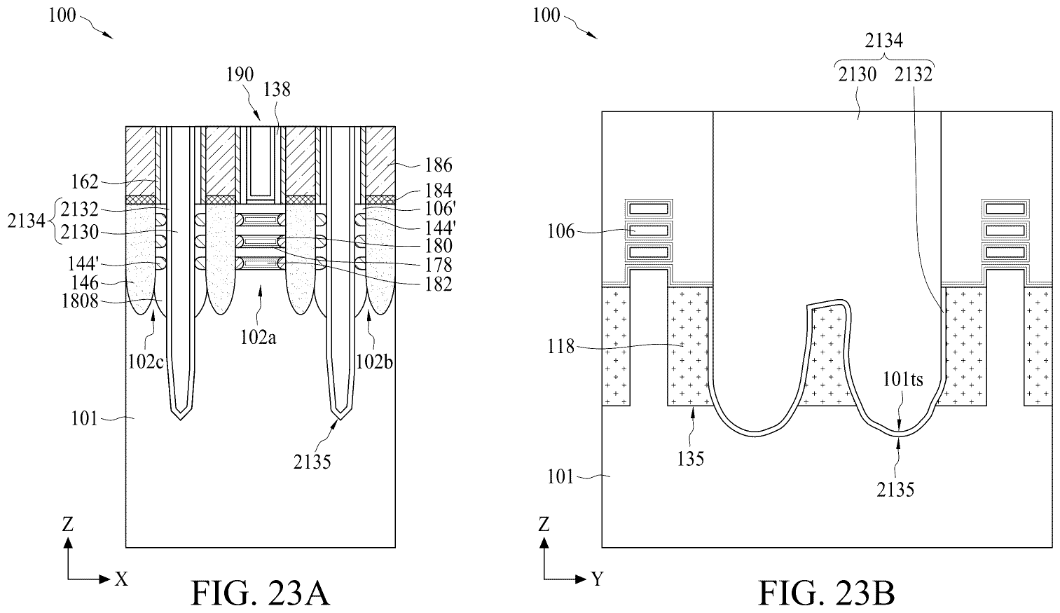

In FIGS. 23A and 23B, the gate electrode layer 182 may optionally be subject to one or more metal gate etching back (MGEB) processes. The MGEB processes are performed so that the top surfaces of the gate electrode layer 182 and the gate dielectric layer 180 are recessed to a level below the top surface of the gate spacers 138. In some embodiments, the gate spacers 138 are also recessed to a level below the top surface of the ILD layer 164. A self-aligned contact layer 192 is formed over the gate electrode layer 182. The self-aligned contact layer 192 may be a dielectric material (e.g., SiN) having an etch selectivity relative to the ILD layer 164. The self-aligned contact layer 192 protects the gate electrode layer 182 during formation of the contact openings. A silicide layer 184 is then formed on the epitaxial source/drain features 146, and a S/D contact 186 is formed in the contact opening on the silicide layer 184. The contact 186 may include an electrically conductive material, such as Ru, Mo, Co, Ni. W, Ti, Ta, Cu, Al, TiN, or TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

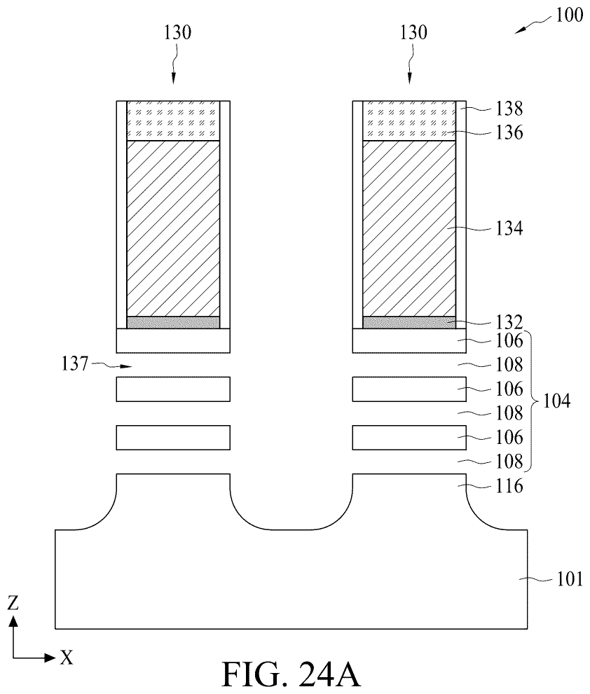

FIGS. 24A, 25A, 26A, 27A, and 28A illustrate the use of sacrificial dielectric layers that can be used to replace the embodiments shown in FIGS. 7A-7C to 8A-8C. In FIG. 24A, the second semiconductor layers 108 are removed. The removal of the second semiconductor layers 108 forms openings 137. The second semiconductor layers 108 may be removed by a selective etch process, such as a selective dry etch process, a selective wet etch process, or a combination thereof. The selective etch process does not substantially affect the gate spacers 138, the first semiconductor layers 106, the sacrificial gate electrode layers 130, and the substrate 101. In some embodiments, the selective etch process is a selective wet etching process. In cases where the second semiconductor layers 108 are made of SiGe and the first semiconductor layers 106 are made of silicon, the second semiconductor layer 108 can be selectively etched using an etchant such as, but not limited to, ammonium hydroxide (NH₄OH), tetramethylammonium hydroxide (TMAH), ethylenediamine pyrocatechol (EDP), or potassium hydroxide (KOH) solutions.

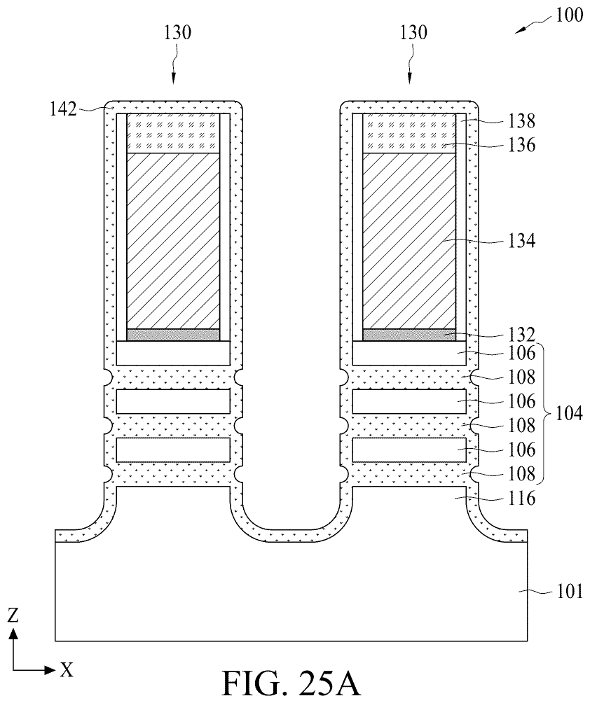

In FIG. 25A, a sacrificial dielectric material 142 is formed in the openings 137 and on the exposed surfaces of the semiconductor device structure 100. In some embodiments, the sacrificial dielectric material 142 is an oxide formed by flowable chemical vapor deposition (FCVD) process. In some embodiments, the oxide is a carbon-containing silicon oxide. The use of the sacrificial dielectric material 142 helps to preserve surface profile of the first semiconductor layers 106 during the subsequent sheet (or channel) formation stage. In traditional cases where the second semiconductor layers 108 include Ge and the first semiconductor layers 106 include silicon, the Ge in the second semiconductor layers 108 may diffuse into and react with Si to form SiGe due to high temperature used during the formation of the subsequent epitaxial S/D features 146. When the second semiconductor layers 108 are selectively removed during the sheet formation stage, a surface portion of the first semiconductor layers 106, which is now SiGe due to prior reaction with Ge, will also be removed. The removal of the second semiconductor layers 108 therefore induces extra silicon loss in the surface portion of the first semiconductor layers 106, resulting in thickness reduction and/or concave-like damage to the first semiconductor layers 106. When the thickness of silicon nanosheet channel layers (i.e., first semiconductor layers 106) is affected, the channel resistance (R_{ch}) of the nanosheet channel layers may increase and the ability of the nanosheet channel layers to conduct current flow (e.g., DC) may be reduced. By replacing the second semiconductor layers 108 with a sacrificial dielectric layer 142 prior to formation of epitaxial S/D features 146, there is minimum reaction between the first semiconductor layers 106 and the sacrificial dielectric layer 142 during the subsequent formation of the S/D features 146, and the sacrificial dielectric layer 142 can be removed with an enhanced etch selectivity over the first semiconductor layers 106. Since the surface profile of the first semiconductor layers 106 remains substantially intact during the sheet formation stage, the channel resistance of the nanosheet channel layers is not increased and the issues discussed herein are avoided.

The concept of the sacrificial dielectric layer 142 is applicable to various embodiments shown in this disclosure.

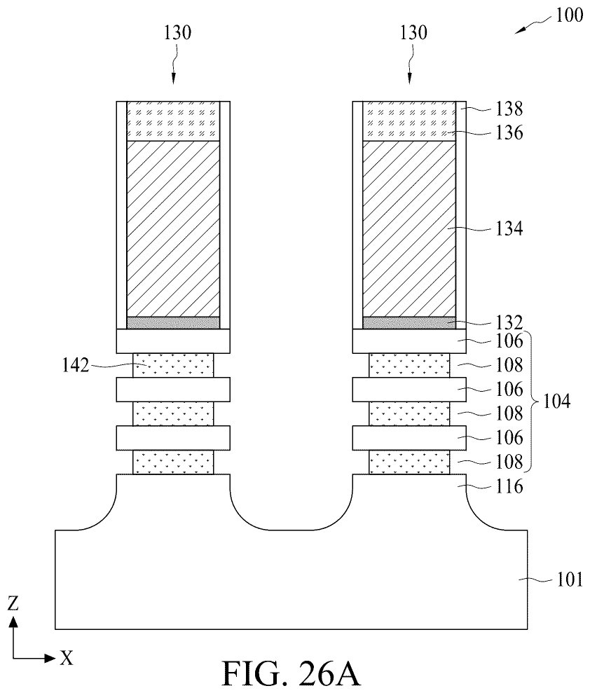

In FIG. 26A, an etch back process is performed to remove portions of the sacrificial dielectric layers 142 other than the portions of the sacrificial dielectric layers 142 formed in the openings 137 (FIG. 24A). In some embodiments, the etch back process is an anisotropic etching process. The etch back process may be a selective etch process that removes the sacrificial dielectric layers 142 but does not substantially affect the sacrificial gate structures 130, the gate spacers 138, the first semiconductor layers 106, and the substrate 101. The selective etch process is performed until edge portions of each sacrificial dielectric layer 142 between first semiconductor layers 106 are removed. Therefore, the majority of the sacrificial dielectric layers 142 between the first semiconductor layers 106 remains intact after the etch back process.

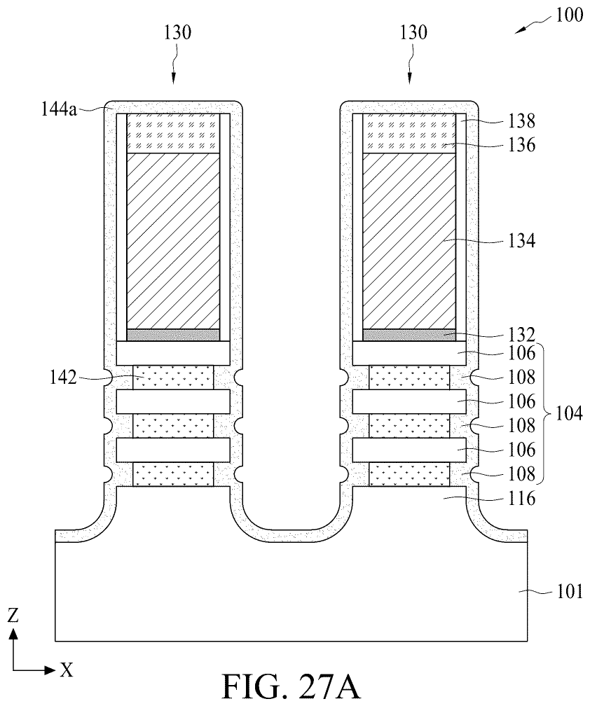

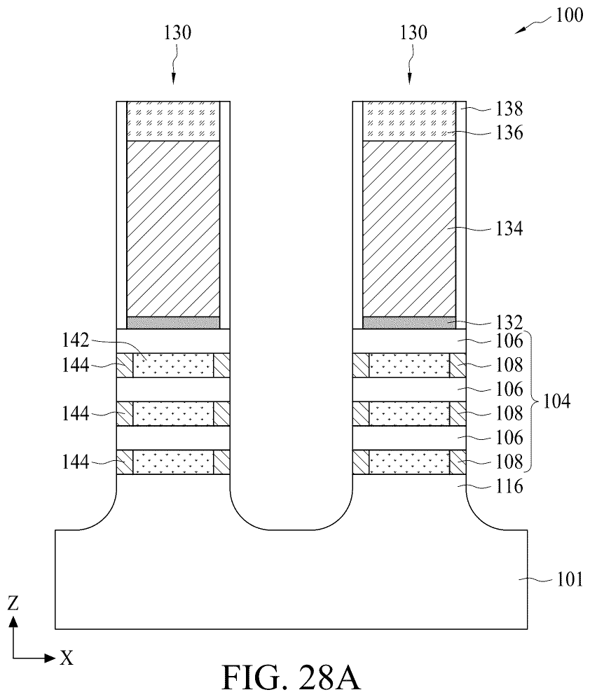

In FIG. 27A, after removing edge portions of the sacrificial dielectric material 142, a dielectric layer 144a is deposited in the cavities formed as a result of removal of the edge portions of the sacrificial dielectric layer 142. The dielectric layer 144a in the cavities forms dielectric spacers 144, as shown in FIG. 28A. The dielectric layer 144a may be made of a dielectric material, such as SiO₂, Si₃N₄, SiC, SiCP, SiON, SiOC, SiCN, SiOCN, and/or other suitable material. The dielectric layer 144a may be deposited as a conformal dielectric layer using a conformal deposition process, such as ALD.

In FIG. 28A, an anisotropic etching is performed to remove portions of the conformal dielectric layer 144a other than the dielectric layer 144a formed in the cavities. The dielectric layer 144a in the cavities forms dielectric spacers 144, and are protected by the first semiconductor layers 106 during the anisotropic etching process. The sacrificial dielectric layer 142 is capped between the dielectric spacers 144 along the X direction. In some embodiments, the dielectric spacers 144 and the sacrificial dielectric material 142 include different materials having different etch selectivity.

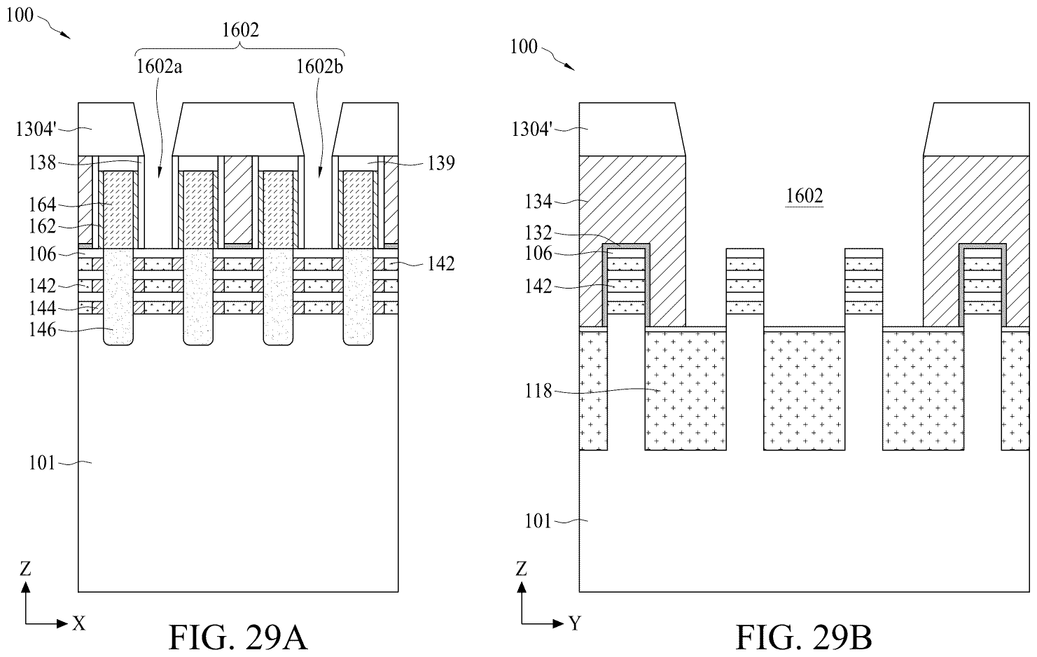

After the dielectric spacers 144 are formed, the S/D features 146, the CESL 162, the cap layer 139 are formed, as those discussed above with respect to FIGS. 9A-9C to 10A-10C. As discussed above with respect to FIGS. 12A-12B to 14A-14B, a mask structure (e.g., the mask structure 1302) is then formed on top of the semiconductor device structure 100. Likewise, the mask structure is patterned to form patterned mask layer 1304′ exposing the sacrificial gate structures 130. The exposed sacrificial gate structures (e.g., sacrificial gate electrode layer 134 and the sacrificial gate dielectric layer 132) are selectively removed to form trench openings 1602a, 1602b (collectively referred to as trench openings 1602). The trench openings 1602 expose the gate spacers 138 and the first semiconductor layers 106, as shown in FIGS. 29A and 29B. The sacrificial gate structures may be removed using chlorine containing gases, such as SiCl₄, BCl₃, Cl₂, CHCl₃, CCl₄, and/or BCl₃, bromine-containing gas, such as HBr and/or CHBr₃, iodine-containing gas, other suitable gases and/or plasmas, and/or combinations thereof.

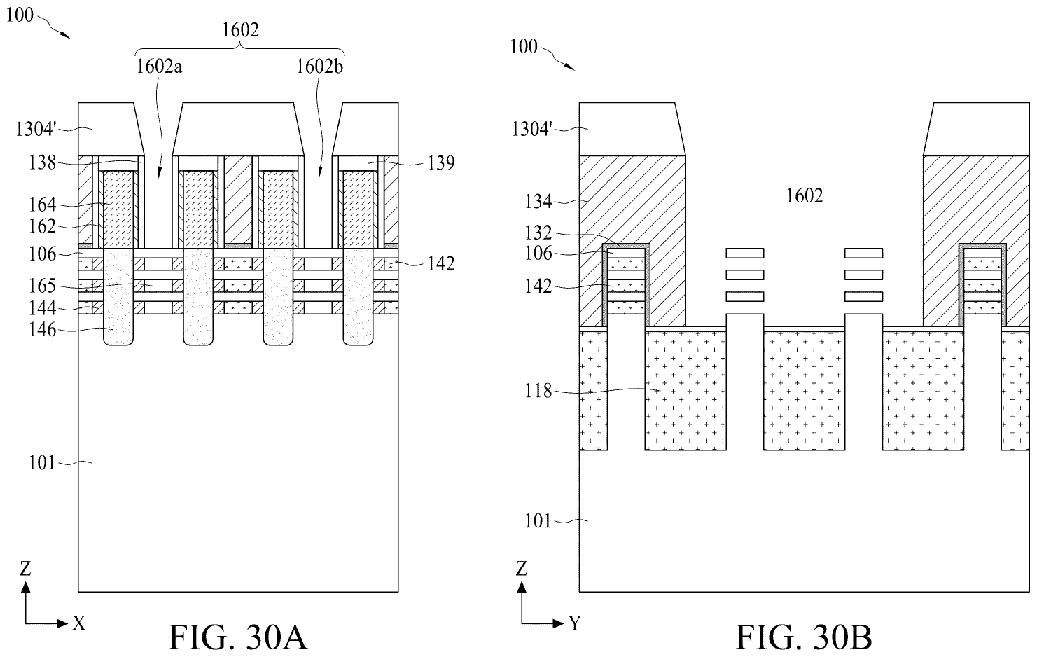

In FIGS. 30A and 30B, the exposed sacrificial dielectric layers 142 are removed. The removal of the sacrificial dielectric layers 142 forms an opening 165 between the first semiconductor layers 106. The sacrificial dielectric layers 142 may be removed using any suitable etch process. The etchant of the etch process is chosen to selectively remove the sacrificial dielectric layers 142 without affecting the gate spacers 138 and the dielectric spacers 144. After the removal of the sacrificial gate structures 130, the first semiconductor layers 106 and the dielectric spacers 144 are exposed to the trench opening 165. The sacrificial dielectric layers 142 disposed between the first semiconductor layers 106 help preserve the integrity and surface profile of the first semiconductor layers 106 during the removal process.

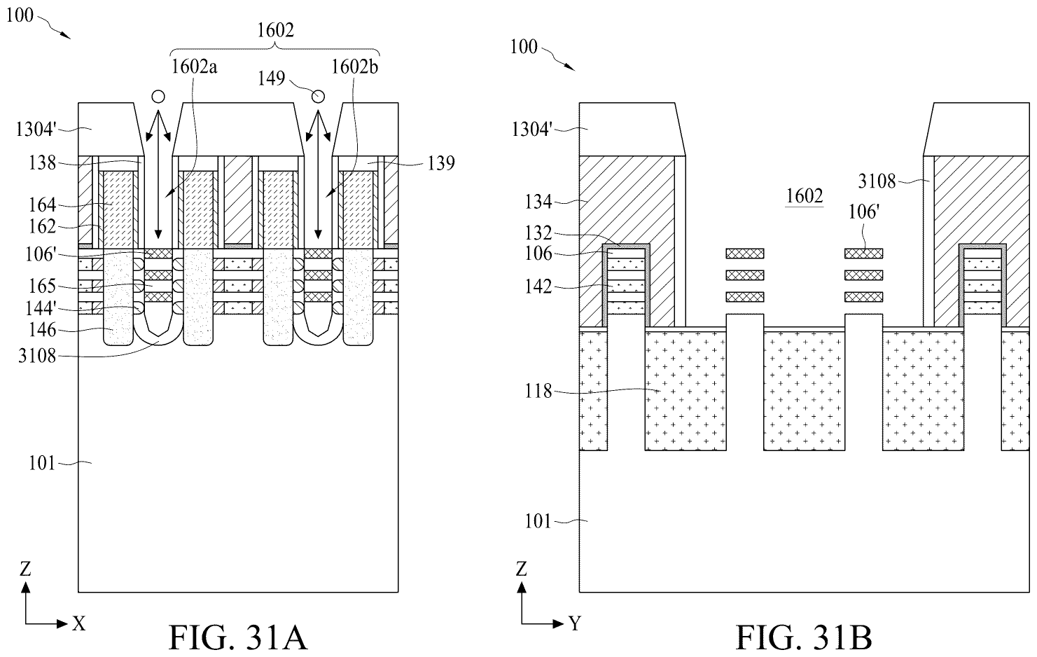

In FIGS. 31A and 31B, after removal of the sacrificial dielectric layers 142, the semiconductor device structure 100 is subjected to a pre-treatment process 149. The pre-treatment process 149 may be any suitable doping process configured to dope impurities (e.g., Group III elements such as boron, aluminum, gallium, etc.) into the exposed first semiconductor layers 106 and a surface (e.g., sidewalls) of the trench openings 1602. Likewise, the doped regions form a protection barrier 3108 in the exposed surfaces of the first semiconductor layers 106 and sidewalls of the trench openings 1602. The doping of impurities enhances etch resistance of the S/D features 146 during the subsequent etch process, enabling damage-free, simple epitaxy structures of the S/D features 146 even if the lithography mask overlay shift happens.

The pre-treatment process 149 may be the treatment process discussed in the first semiconductor etch process 141 above. In some embodiments, the pre-treatment process 149 is performed concurrently or intermittently with the etch process used to remove the sacrificial dielectric layers 142. In cases where the pre-treatment process 149 is performed concurrently with the etch process, the dopant gas may flow concurrently with the etchants. In cases where the pre-treatment process 149 is performed intermittently with the etch process, the dopant gas and the etchants may be provided sequentially in a cyclic fashion until the sacrificial dielectric layers 142 are moved and the dopants are doped in the target regions. In either case, the temperature of the pre-treatment process 149 is controlled so that the P-type dopants may not be activated. In any case, the P-type dopants in the doped regions (e.g., doped first semiconductor layers 106′ and the doped dielectric spacers 144′) form a protection barrier 3108 for the trench openings 1602. The S/D features 146 can be protected by the protection barrier 3108 during the subsequent etching process. In cases where the dopant gas containing Group III dopants (e.g., boron), the doped first semiconductor layers 106′ may have a first concentration of boron, and the doped dielectric spacers 144 may have a second concentration of boron that is lower than the first concentration of boron. The gate spacers 138 may have a third concentration of boron that is lower than the second concentration of boron. In some cases, the third concentration of boron is nearly zero.

An exemplary pre-treatment process 149 may include exposing the semiconductor device structure 100 to a plasma generated from one or more dopant gases (e.g., a boron-containing gas such as B₂H₆ or BCl₃) and the dilute gas in a plasma doping chamber. The plasma doping process may be performed at a constant energy of between about 2 keV and about 5 keV, a bias voltage of about −200V to about −20 kV, and a chamber pressure of about 1 mTorr to about 50 mTorr, to dope plasma ions (e.g., boron) into the surface (e.g., sidewalls) of the trench openings 1602. After the plasma doping process, the doped region (e.g., the protection barrier 3108) may have a dopant concentration of boron in a range from about 1.0E15 atoms/cm³ to about 3.0E22 atoms/cm³. The plasma doping process can form an abrupt doping profile junction at a depth of about 5 nm to about 10 nm from surfaces of the trench openings 1602 with a doping profile abruptness of about 1 nm/decade.

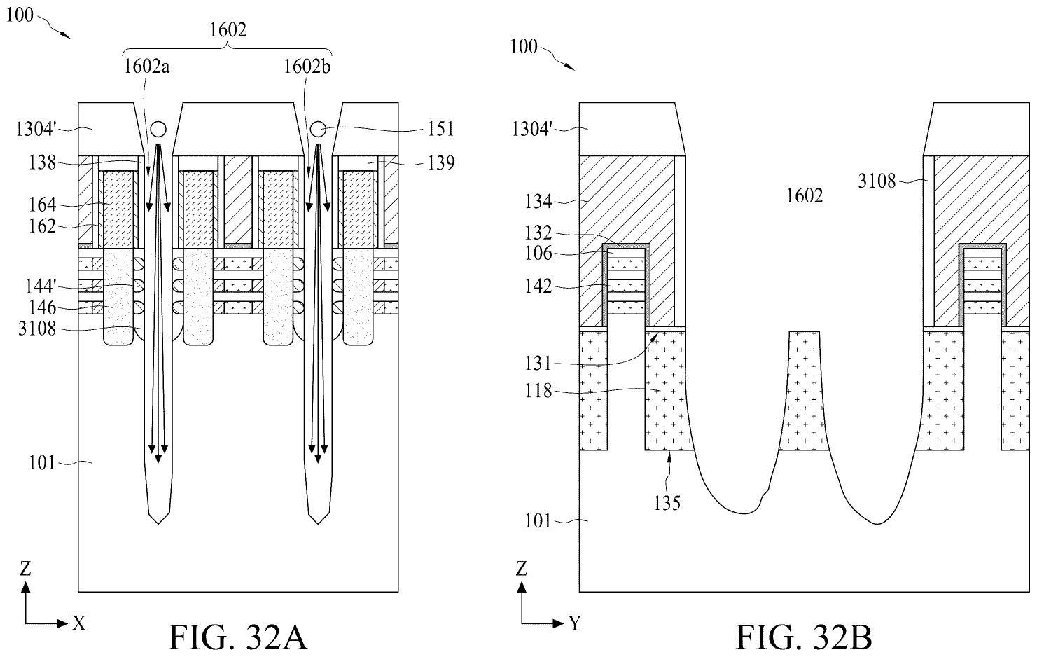

In FIGS. 32A and 32B, a semiconductor etch process 151 is performed to remove the exposed, doped first semiconductor layers 106′, the exposed insulating material 118, and the substrate portion forming the fin structures. The semiconductor etch process 151 may be identical or similar to the second semiconductor etch process 147 discussed above with respect to FIGS. 18A-18B. Likewise, the semiconductor etch process 151 is performed such that the trench openings 1602 are extended with a straight and symmetric sidewall profile with respect to an imaginary line passing through a center of the respective trench openings 1602 in the depth direction of the trench openings 1602. In some embodiments, the pre-treatment process 149 discussed above is not performed during the semiconductor etch process 151. In some embodiments, the pre-treatment process 149 is performed concurrently or intermittently with the semiconductor etch process 151, in a similar fashion as discussed above. The substrate portion of the fin structure may be removed by the semiconductor etch process 151 using a plasma etch process comprising HBr and/or Cl₂. In some embodiments, O₂ and/or CO₂ may be added to HBr and/or Cl₂ based plasma to facilitate dissociation of the plasma by product. In some embodiments, the plasma etch process may be a high density plasma process using process conditions similar to the second semiconductor etch process 147. The semiconductor etch process 151 is performed to extend the trench openings 1602 to an elevation below an interface 135 defined by the substrate 101 and the insulating material 118.

One or more etch conditions may be controlled to achieve low selectivity etch between silicon (e.g., substrate 101) and silicon oxide (e.g., insulating material 118). For example, a low-pressure process (e.g., chamber pressure below about 50 mTorr) and/or high bias power to the substrate pedestal (e.g., greater than 300 V) may be utilized during the semiconductor etch process 151 to compensate for etch selectivity needed for removing the insulating material 118 and the substrate portion of the fin structures. In some embodiments, boron trichloride (BCl₃), or the like, may be used to enhance the etch selectivity of silicon oxide, achieving low selective etch between silicon and silicon oxide. In some embodiments, the bottom surface of the trench openings 1602 may be at an elevation within a well region or an accumulation region of the substrate 101.

In cases where the pre-treatment process 149 is not used during the semiconductor etch process 151, the fin structures exposed through the trench openings 1602 and a portion of the insulating material 118 surrounding the fin structures are removed, leaving the majority of the insulating material 118 between the two adjacent fin structures substantially intact. In such cases, the top of the insulating material 118 between two adjacent isolation trenches 1802 is slightly below an interface 131 defined by the insulating material 118 and the sacrificial gate electrode layer 134 (or the sacrificial gate dielectric layer 132), but above the halfway point of the height of the insulating material 118, as shown in FIG. 32B.

In cases where the pre-treatment process 149 is performed concurrently or intermittently with the semiconductor etch process 151, the fin structures exposed through the trench openings 1602 and a portion of the insulating material 118 surrounding the fin structures are greatly removed, resulting in the insulating material 118 between the two adjacent fin structures with a top below the halfway point of the height of the insulating material 118, as shown above in FIG. 18B-1. In some cases, the top of the insulating material 118 is below a center line “C” extending laterally through the halfway point of the height of the insulating material 118, and the top of the remaining insulating material 118 may have a tapering profile, as shown above in FIG. 18B-2.

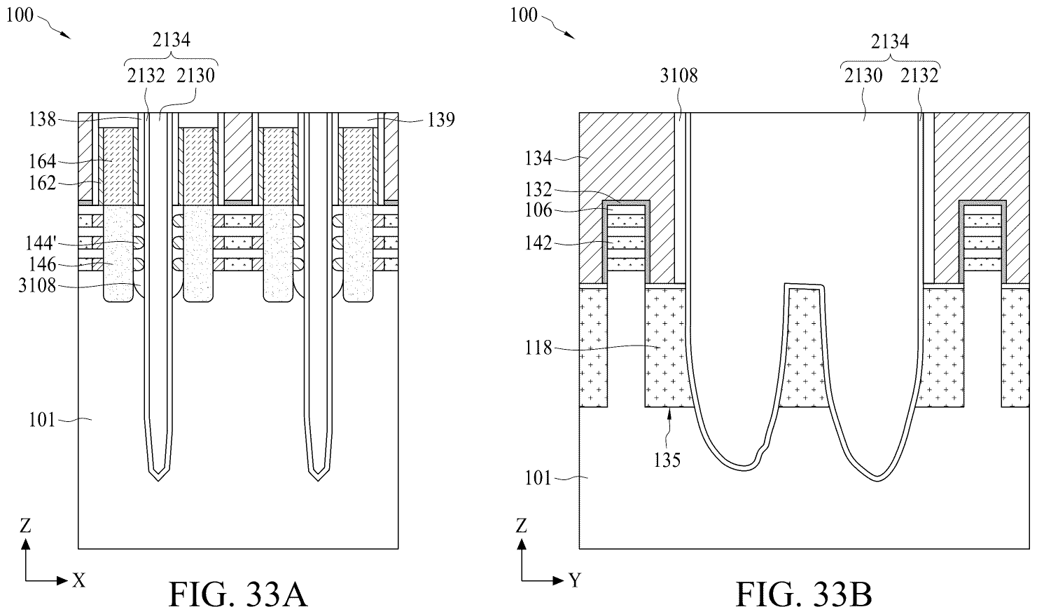

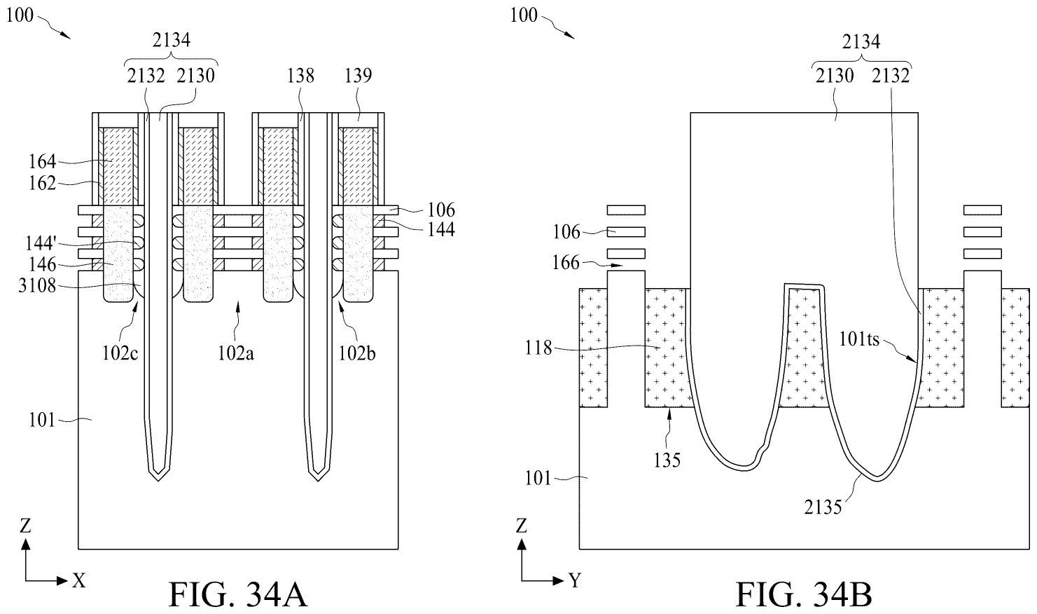

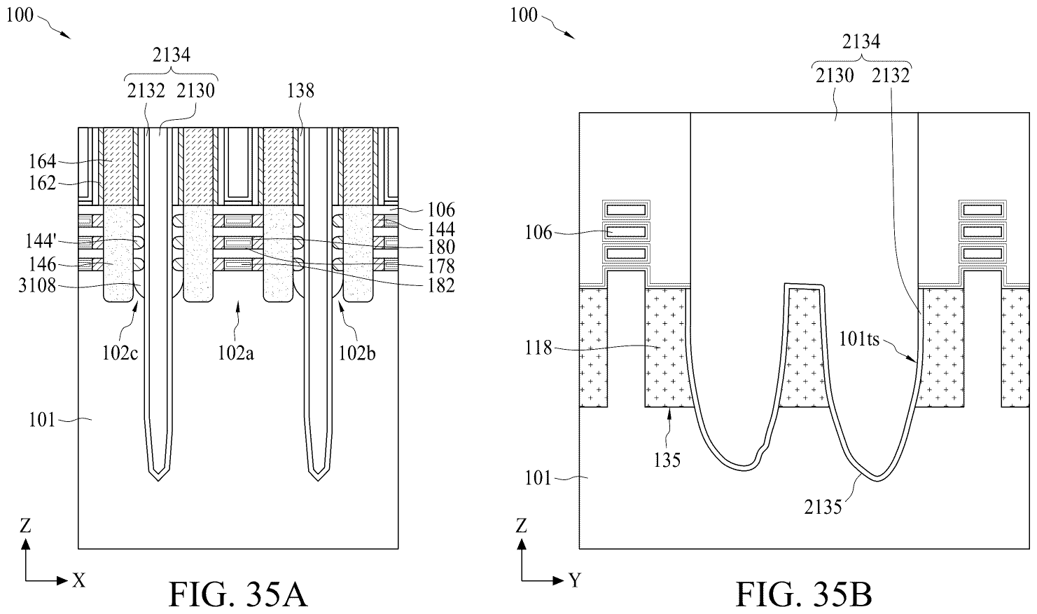

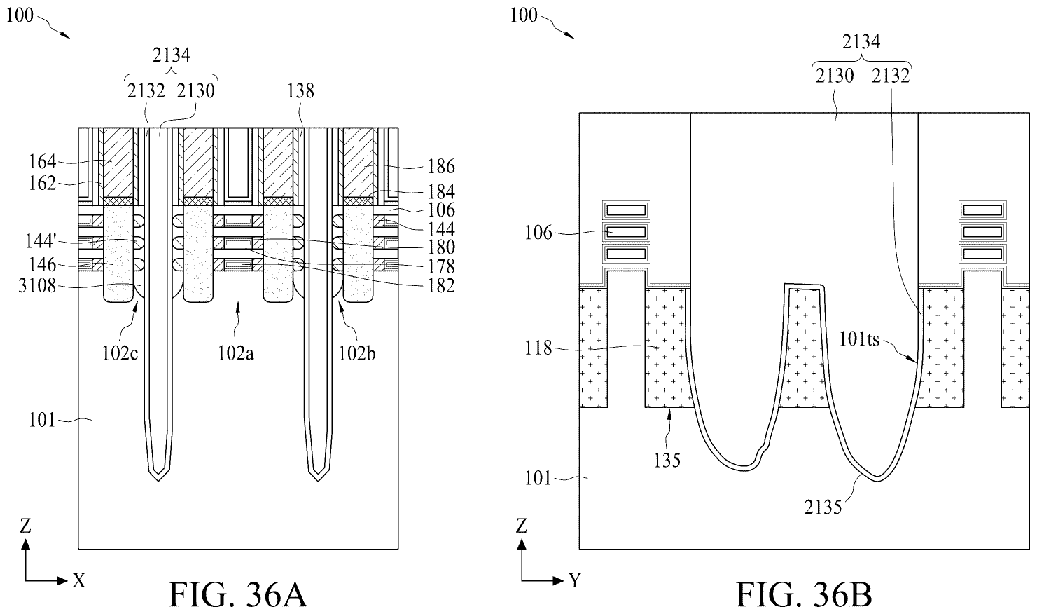

In FIGS. 33A and 33B, the trench openings 1602 are filled with a dielectric liner 2132a and a dielectric material 2130 to form isolation trench structures (i.e., CPODE trenches) 2134, in a similar fashion as discussed above with respect to FIGS. 19A-19B and 20A-20B. In FIGS. 34A and 34B, the sacrificial gate structures and the sacrificial dielectric layers 142 are removed, in a similar fashion as discussed above with respect to FIGS. 21A and 21B. In FIGS. 35A and 35B, a replacement gate structure (IL 178, gate dielectric layer 180, and gate electrode layer 182) is formed, in a similar fashion as discussed above with respect to FIGS. 22A and 22B. In FIGS. 36A and 36B, silicide layers 184 and S/D contacts 186 are formed, in a similar fashion as discussed above with respect to FIGS. 23A and 23B.

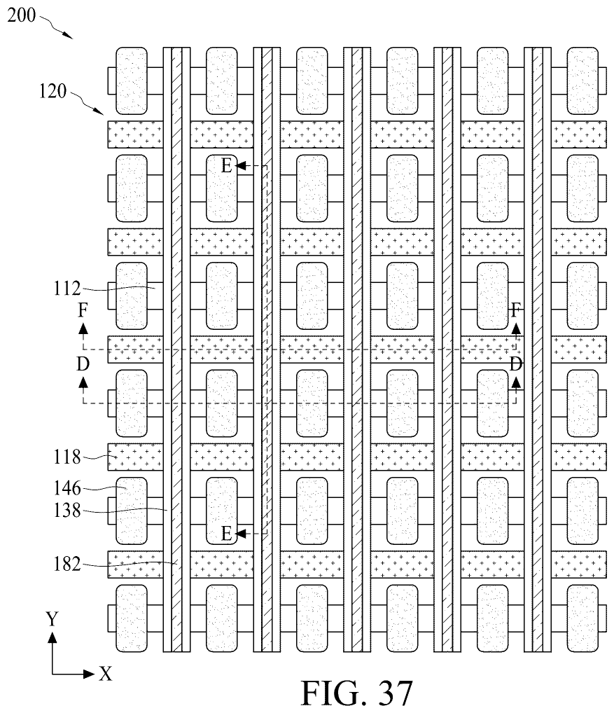

While various embodiments in FIGS. 1-36B describe a CPODE-first processing methods, i.e., during front-end-of-line (FEOL) processing before metal gate formation, the embodiments are equally applicable to a CPODE-last processing method (or so-called CMODE process), i.e., during middle-end-of-line (MEOL) processing after metal gate formation is formed. FIG. 37 is a top view of the semiconductor device structure 200 in accordance with some embodiments. The semiconductor device structure 200 is similar to the semiconductor device structure 100 and some components of the semiconductor device structure 200, such as the ILD layer 164, the gate dielectric layer 180, and the CESL 162, etc., are omitted in FIG. 37 for the sake of clarity. Furthermore, the locations of the S/D regions 146 and the isolation regions 120 (i.e., insulating material 118) are for illustration and are not exact. As shown in FIG. 37, the semiconductor device structure 200 includes S/D regions 146 formed on opposite sides of the gate electrode layer 182. Each gate electrode layer 182 has a longitudinal axis along the Y direction, while each fin structure 112 has the longitudinal axis along the X direction.

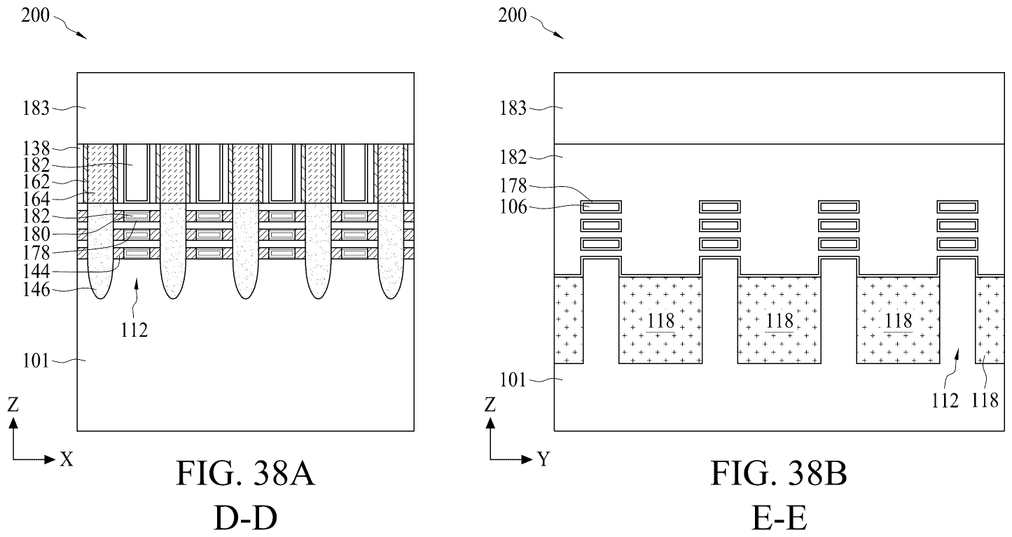

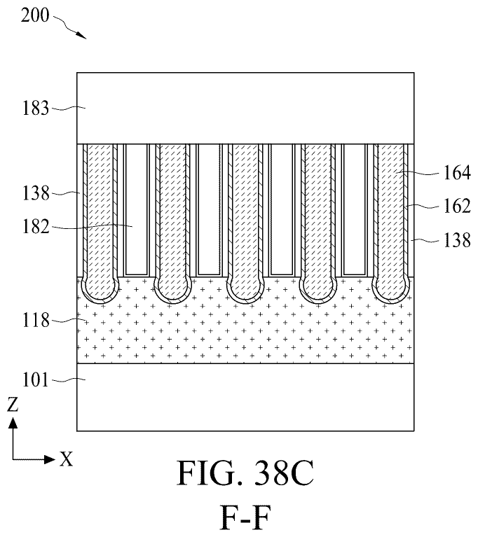

FIGS. 38A-46A are cross-sectional side views of various stages of manufacturing the semiconductor device structure 200 taken along line D-D of FIG. 37, in accordance with some embodiments. The line D-D runs across the fin structures (e.g., fin structures 112) along the X-direction. FIGS. 38B-46B are cross-sectional side views of various stages of manufacturing the semiconductor device structure 200 taken along line E-E of FIG. 37, in accordance with some embodiments. The line E-E runs across the fin structures (e.g., fin structures 112) along the Y-direction. FIGS. 38C-46C are cross-sectional side views of various stages of manufacturing the semiconductor device structure 200 taken along line F-F of FIG. 37, in accordance with some embodiments. The line F-F runs across the STI regions (e.g., isolation regions 120) along the X-direction. As shown in FIGS. 38A-38C, a mask layer 183 is formed on the top surfaces of the gate dielectric layer 180, the gate spacers 138, gate electrode layers 182, the CESL 162, and the ILD layer 164. The mask layer 183 may include a dielectric layer, such as SiN, or a semiconductor material, such as amorphous silicon.

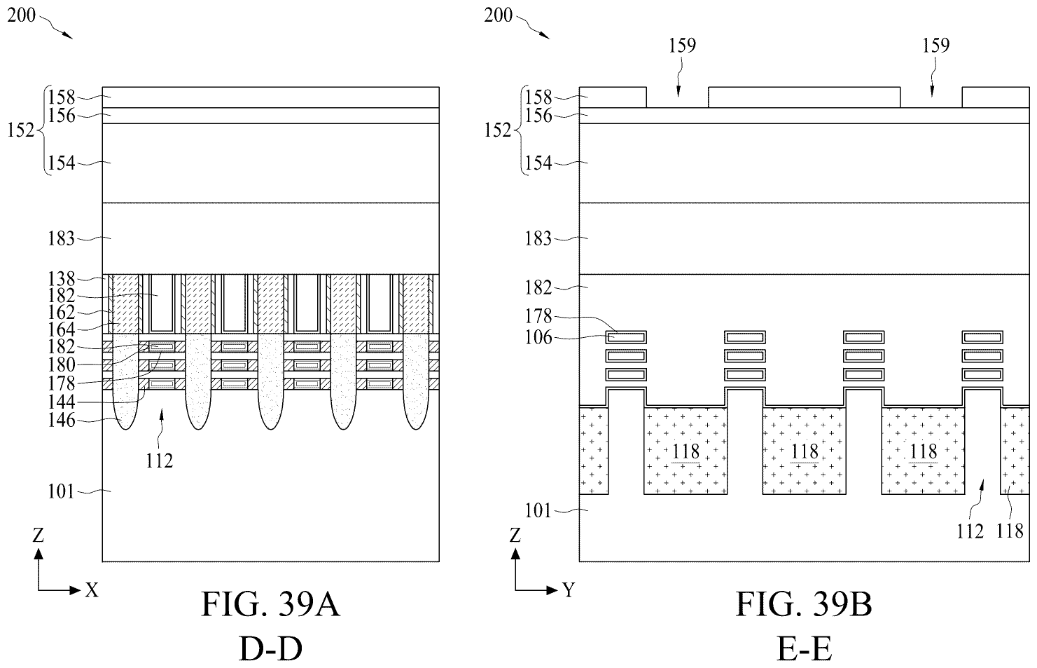

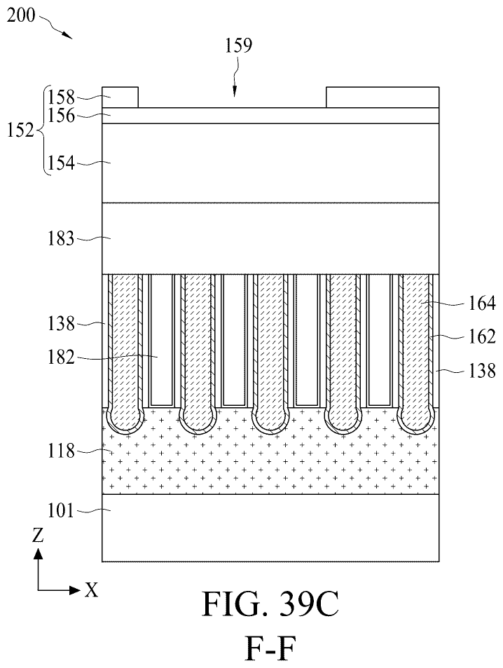

In FIGS. 39A-39C, a mask structure 152 is formed on the mask layer 183. In some embodiments, the mask structure 152 is a tri-layer photoresist. For example, the mask structure 152 may include a bottom layer 154 and a middle layer 156 disposed on the bottom layer 154. The bottom layer 154 and the middle layer 156 are made of different materials such that the optical properties and/or etching properties of the bottom layer 154 and the middle layer 156 are different from each other. In some embodiments, the bottom layer 154 may be a carbon layer, and the middle layer 156 may be a silicon-rich layer designed to provide an etch selectivity between the middle layer 156 and the bottom layer 154. The mask structure 152 further includes a photoresist layer 158 that may be a chemically amplified photoresist layer and can be a positive tone photoresist or a negative tone photoresist. The photoresist layer 158 may include a polymer. The photoresist layer 158 is patterned to have openings 159 formed therein. The openings 159 are arranged to align with one or more gate electrode layers 182. In some embodiments, the openings 159 may extend across at least three gate electrode layers 182 along the X-direction.

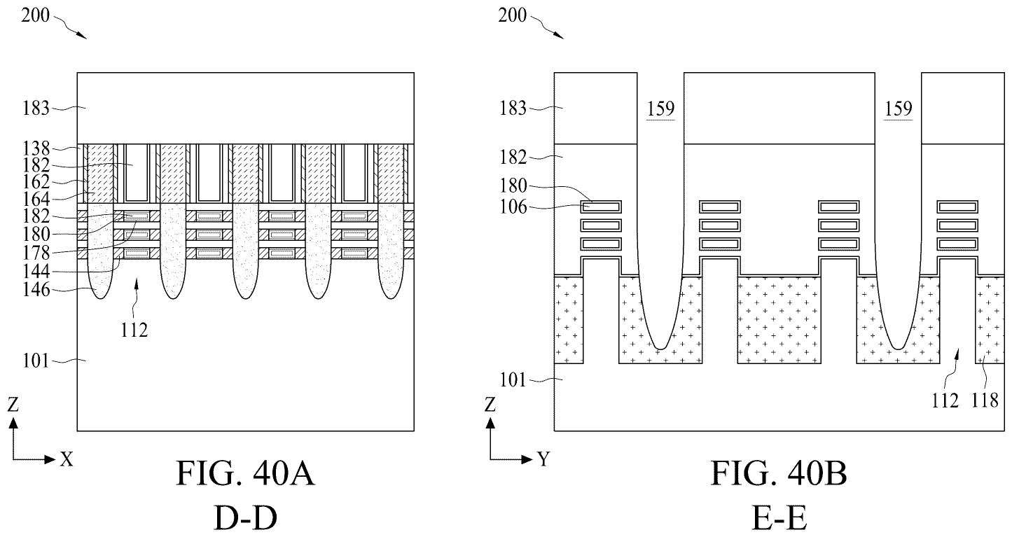

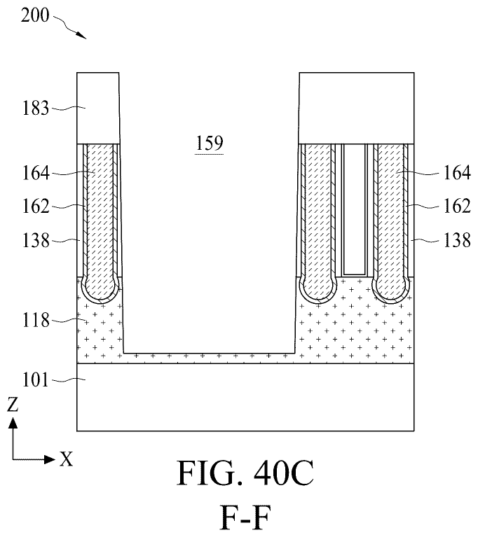

In FIGS. 40A-40C, the openings 159 are extended into the middle layer 156, the bottom layer 154, and the mask layer 180. The mask structure 152 may be removed after the openings 159 are extended into the mask layer 180. Portions of the gate electrode layers 182 and gate dielectric layers 180 are exposed in the openings 159. Next, the openings 159 are extended through the gate electrode layers 182, the gate dielectric layer 180, and into the insulating material 118 by removing the exposed portions of the gate electrode layers 182, the gate dielectric layer 180, and the insulating material 118, as shown in FIG. 40B and 40C. The openings 159 may be formed by one or more etch processes. The openings 159 extend a thickness into the insulating material 118 so that a thin layer of the insulating material 118 remains on the exposed surface of the substrate 101. As shown in FIG. 40C, in some embodiments, the gate spacers 138 are protected by the mask layer 183 and are not removed during the removal of the portions of the gate electrode layers 182 and gate dielectric layer 180.

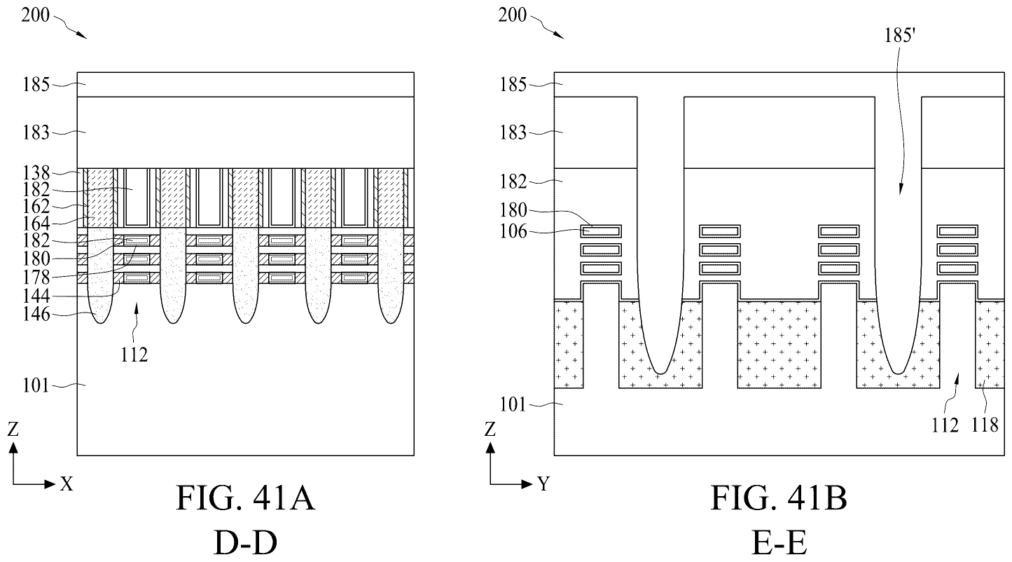

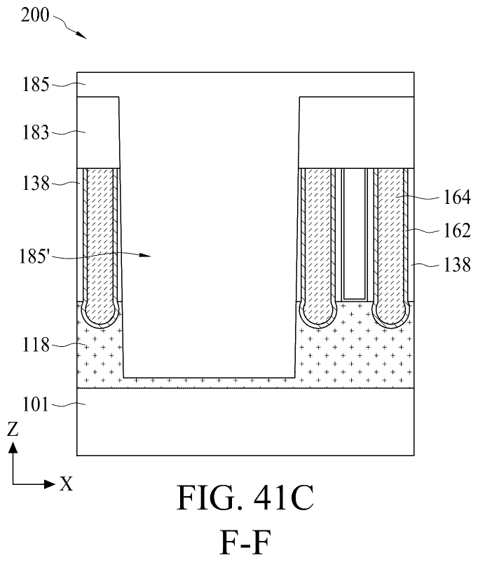

In FIGS. 41A-41C, a dielectric material 185 is deposited in the openings 159. The dielectric material 185 within the openings 159 forms cut metal gate (CMG) structures 185′. The CMG structures 185′ divide a gate electrode layer 182 into two or more portions, and the two or more portions may be controlled independently. The dielectric material 185 may be a low etch resistivity material. In some embodiments, the dielectric material 185 is a nitrogen-containing material, such as silicon nitride, silicon oxynitride (SiON), SiOCN, SiCN; an oxygen-containing material, such as silicon oxide (SiO₂); a low-K dielectric material; or any suitable dielectric material. In one exemplary embodiment, the dielectric material 185 is a nitride. The dielectric material 185 may be formed by any suitable process, such as a CVD, PECVD, FCVD, or ALD process.

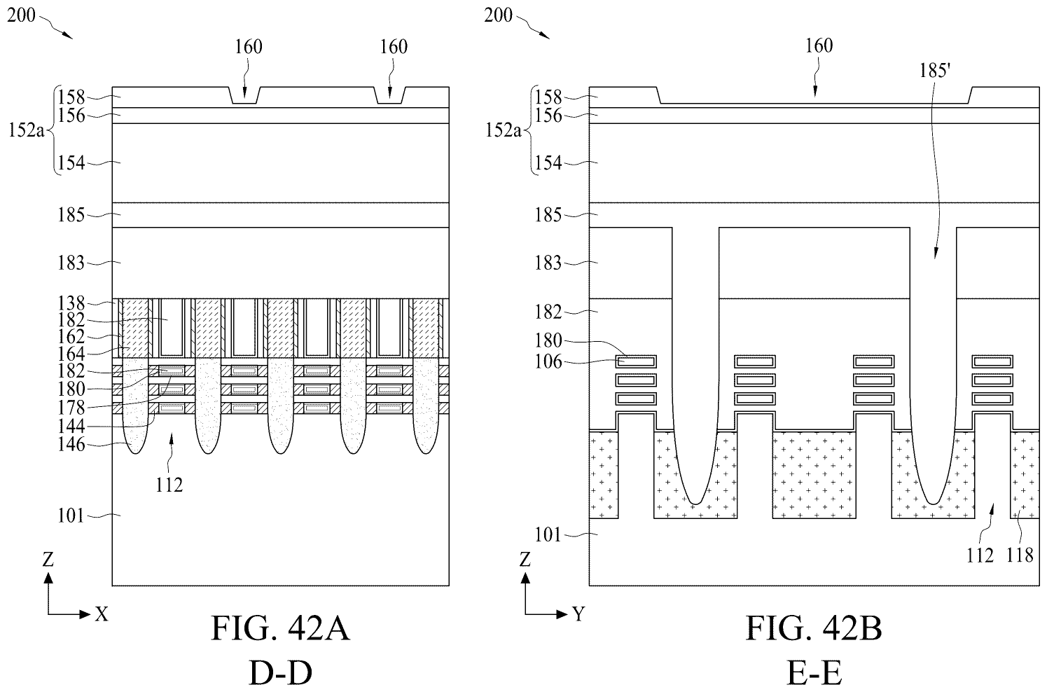

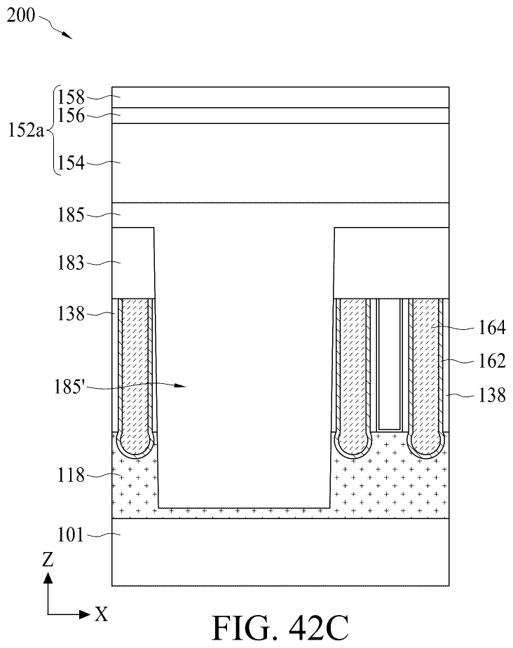

In FIG. 42A-42C, a mask structure 152a, such as the mask structure 150, is formed on the dielectric material 185. Likewise, the mask structure 152a is a tri-layer photoresist including a bottom layer 154, a middle layer 156 disposed on the bottom layer 154, and a photoresist layer 158. The photoresist layer 158 is patterned to have openings 160 formed therein. The patterned photoresist layer 158 is used as a mask during a subsequent process, such as one or more photolithographic processes, to transfer the pattern (i.e., openings 160) in the photoresist layer 158 into the middle layer 156, the bottom layer 154, the dielectric material 184, and the mask layer 183.

In various embodiments, the openings 160 are arranged to cross over a portion of the CMG structures 185′. The openings 160 define an isolation region to be formed in the substrate portions of the fin structures 112. The isolation region may be disposed between neighboring active regions. The term “active region” refers to a region where transistors are formed. As will be discussed in more detail below, the isolation regions may be formed by performing a fin-cut (or sheet-cut) process and filling the fin-cut (or sheet-cut) regions with a dielectric. This fin-cut (or sheet-cut) process may be referred to continuous metal on diffusion edge (CMODE) process. The term “diffusion edge” is equivalently referred to as an active edge, which is an edge abutting adjacent active regions. The CMODE process can be used to reduce gate pitch, thereby increasing the density for multi-gate devices and thus device performance required for aggressively scaled circuits and devices. In any case, the pattern (i.e., openings 160) in the photoresist layer 158 are arranged at locations where portions of the CMG structures 185′ and the replacement gate structures are to be revealed in a later stage.

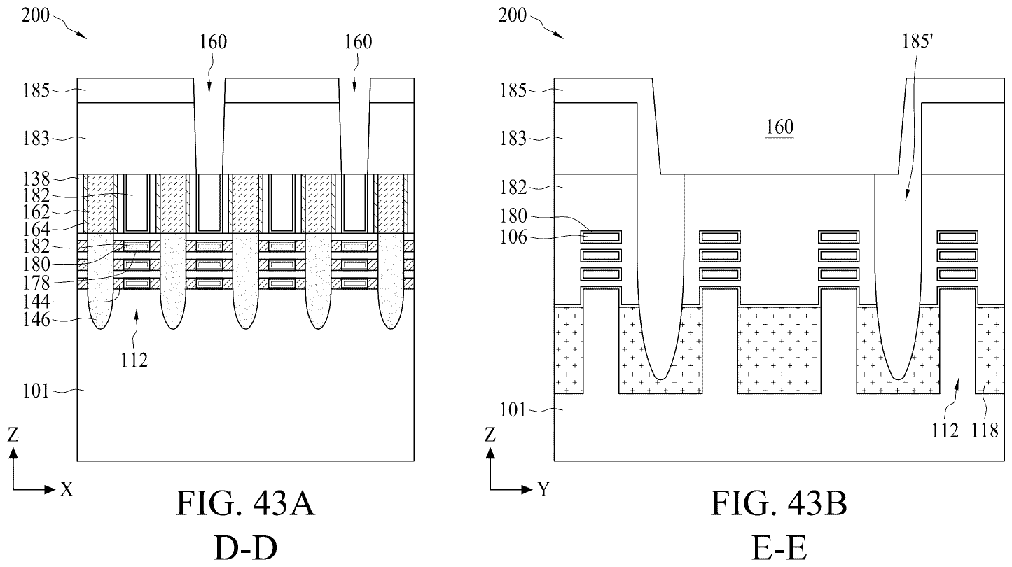

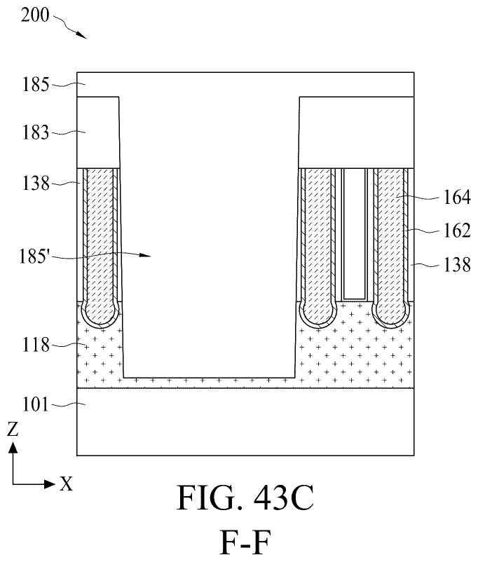

In FIGS. 43A-43C, the patterns (i.e., openings 160) in the photoresist layer 158 are transferred to the mask layer 183 to form patterned mask layer, and the bottom layer 154, the middle layer 156, the photoresist layer 158 are removed. The formation of the patterned mask layer 183 may be achieved by one or more photolithographic processes. As a result of the one or more photolithographic processes, openings 160 are formed in the CMG structures 185′ and the patterned mask layer 158, and a portion of the gate electrode layer 182 is exposed. In some embodiments, the opening 160 exposes a portion of a gate electrode layer 182, and the exposed portion of the gate electrode layer 182 extends across multiple fin structures 112. In some embodiments, the exposed portion of the gate electrode layer 182 extends over two fin structures 112, as shown in FIG. 43B.

The one or more photolithographic processes may stop as soon as the gate electrode layer 182 is exposed. As can be seen, the openings 160 expose portions of the CMG structures 185′ and a plurality of gate electrode layers 182 along the Y direction. The patterned mask layer 183 may then be used to protect active regions during subsequent fin-cut (or sheet-cut) process.

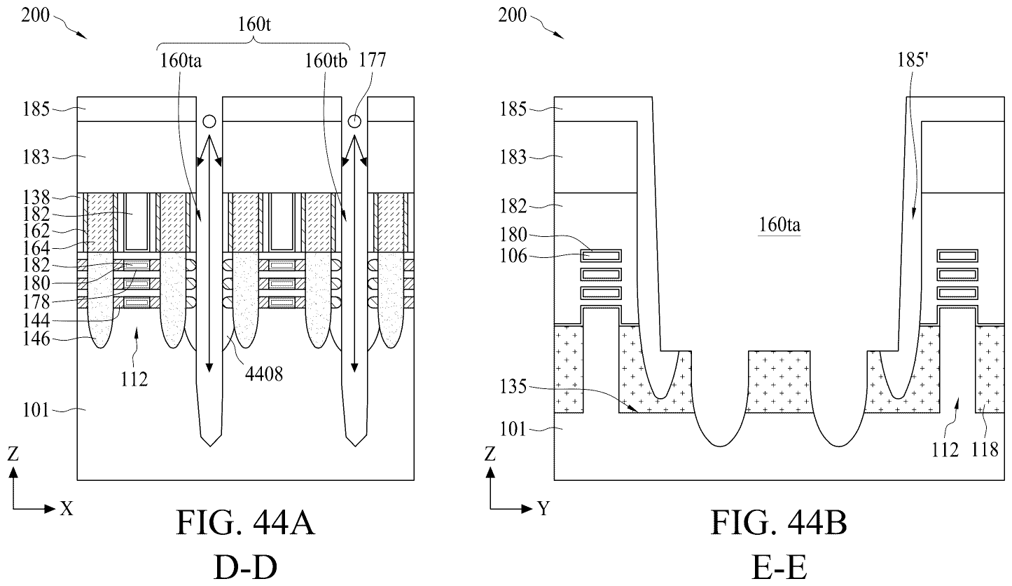

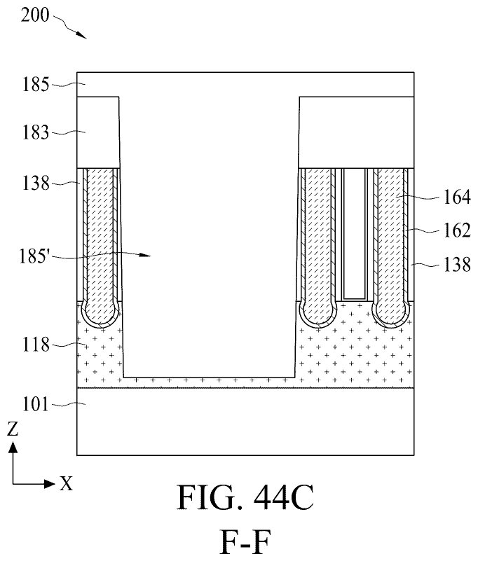

In FIG. 44A-44C, the exposed portions of the gate electrode layer 182, the insulating material 118, the CMG structures 185′, and the fin structures 112 (including the first semiconductor layers 106 and the gate dielectric layer 180 surrounding each of the first semiconductor layers 106) are removed by an etch process 177, using the patterned mask layer 183 as a mask. The etch processes 177 may include the first semiconductor etch process 141, the treatment process, and the second semiconductor etch process 147, and may be performed in a similar fashion as those discussed above with respect to FIGS. 17A-17B and 18A-18B. For example, a first semiconductor etch process of the etch process 177, such as the first semiconductor etch process 141, may be performed to extend the openings 160 through the gate electrode layer 182 and the first semiconductor layers 106 so that the bottom of the openings 160 is at the same elevation as the bottom of the S/D features 146. A second semiconductor etch process of the etch process 177, such as the second semiconductor etch process 147, may be performed to further extend the openings 160 into the substrate 101 to form isolation trenches 160ta, 160tb. Likewise, the treatment process of the etch processes 177, such as the pre-treatment process 149, is performed to dope impurities (e.g., P-type dopants) in the sidewalls of the isolation trenches 160ta, 160tb. The treatment process may be performed concurrently or intermittently with the first semiconductor etch process. The treatment process may or may not be performed with the second semiconductor etch process. In either case, the doped regions (e.g., first semiconductor layers 106 and the dielectric spacers 144) in the surface regime of the isolation trenches 160ta, 160tb serve as a protection barrier 4408 that enhances etch resistance of the S/D features 146 during the subsequent etch process, enabling damage-free, simple epitaxy structures of the S/D features 146 even if the lithography mask overlay shift happens.

As a result of the fin-cut process, isolation trenches 160ta, 160tb (collectively referred to as isolation trenches 160t) are formed and extended into portions of the substrate 101 forming the fin structures 112. The isolation trenches 160t are to be filled with a dielectric material and form CMODE structures. In any case, the isolation trenches 160t (and thus subsequent CMODE structures) are formed with a depth sufficient to block leakage current, which may otherwise flow through epitaxial source/drain features, transistors, and silicon substrates. In some embodiments, the bottom of the isolation trenches 160t may be at an elevation into an accumulation region of the substrate 101.

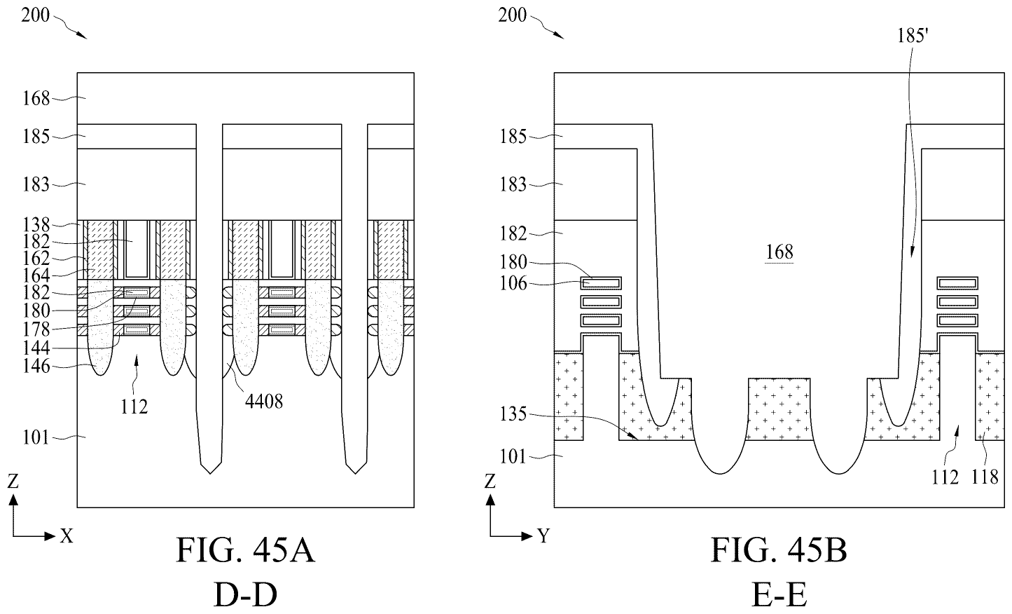

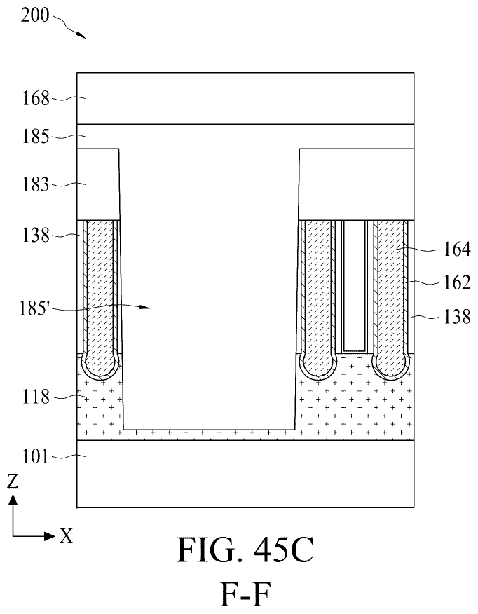

In FIGS. 45A-45C, a refill dielectric material 168 is formed in the isolation trenches 160t. In some embodiments, a dielectric liner (not shown) may be disposed between the dielectric material 168 and the exposed surfaces of the isolation trenches 160t. The dielectric material 168 and the dielectric liner filled within the isolation trenches 160t form isolation trench structures 167ta, 167tb (collectively referred to as CMODE structures 167. The dielectric material 168 and the dielectric liner may be made of an oxygen-containing material, such as silicon oxide (SiO₂); a nitrogen-containing material, such as silicon nitride, silicon oxynitride (SiON), SiOCN, SiCN; a low-K dielectric material; or any suitable dielectric material. The dielectric material 168 may include a material chemically different than the and the dielectric liner, and may be formed by any suitable process, such as a CVD, PECVD, FCVD, or ALD process. The dielectric liner may be deposited by a conformal process, such as ALD.

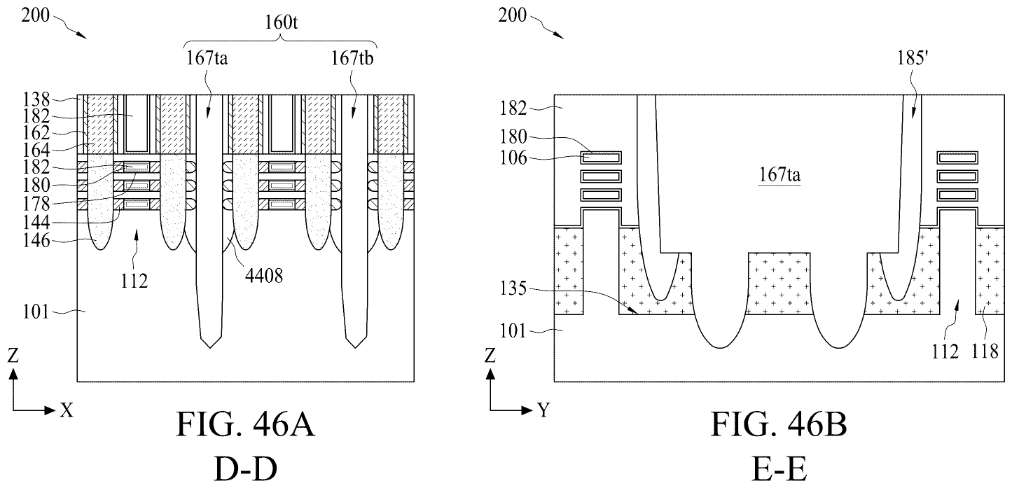

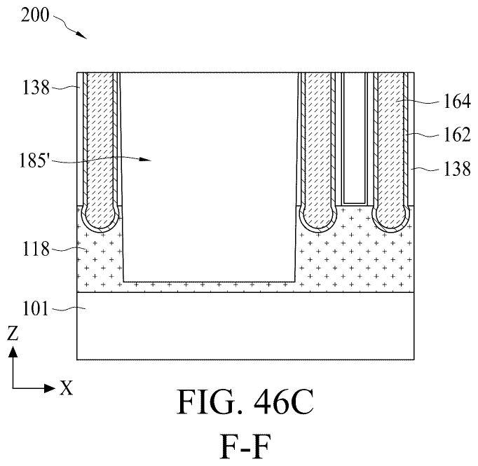

In FIGS. 46A-46C, once the isolation trenches 160t are filled, a planarization process, such as a CMP process, may be performed to remove portions of the dielectric material formed over the patterned mask layer 183. The planarization process may continue until a portion of the ILD layer 164 is exposed. In some embodiments, the isolation trench structures 167ta along the X-direction has a first dimension and CMG structure 185′ along the X-direction has a second dimension greater than the first dimension. The top surfaces of the isolation trench structures 167ta, 167tb and the CMG structure 184′ are substantially co-planar.

It is understood that the semiconductor device structures 100, 200 discussed above may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structures 100, 200 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Embodiments of the present disclosure provide improved isolation trench structures (e.g., CPODE/CMODE structures) having a boron-doped protection barrier disposed between S/D features and the isolation trench structures. The protection barrier enhances etch resistance of the S/D features during the subsequent etch process, enabling damage-free, simple epitaxy structures of the S/D features even if the lithography mask overlay shift happens. The isolation trench structure may extend into the well region of the substrate to block leakage current through EPI-transistors-substrate-EPI.

A semiconductor device structure is described. The structure includes a substrate, an insulating material disposed on the substrate, a first fin structure extending upwardly from the substrate through the insulating material, a second fin structure extending upwardly from the substrate through the insulating material, a source/drain (S/D) feature disposed between the first and second fin structures, and an isolation trench structure extending through the first fin structure and into the substrate, wherein the isolation trench structure has a doped sidewall region disposed between and in contact with the S/D feature and the isolation trench structure.

Another embodiment is a method for forming a semiconductor device structure. The method includes forming a plurality of fin structures from a substrate, each fin structure comprising a plurality of semiconductor layers and a plurality of sacrificial layers alternatingly stacked, forming source/drain (S/D) features on opposite sides of the fin structure, forming an isolation trench between two adjacent S/D features by removing exposed portions of the semiconductor layers and the sacrificial layers, subjecting the isolation trench to a doping process to form a doped region in a sidewall of the isolation trench, and filling the isolation trench with a dielectric material.

A further embodiment is a method for forming a semiconductor device structure. The method includes forming a plurality of fin structures from a substrate, each fin structure comprising a plurality of semiconductor layers and a plurality of sacrificial layers alternatingly stacked, forming an insulating material on the substrate, forming a sacrificial gate structure on the insulating material and over a portion of the fin structures, forming a source/drain (S/D) feature on opposite sides of each fin structure, forming a first portion of an isolation trench by removing portions of the sacrificial gate structure and the sacrificial layers to expose the plurality of semiconductor layers of a first fin structure, exposing the isolation trench to a pre-treatment process, forming a second portion of the isolation trench by removing the first fin structure and a portion of the substrate, and filling the isolation trench with a dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a substrate;
an insulating material disposed on the substrate;
a first fin structure extending upwardly from the substrate through the insulating material;
a second fin structure extending upwardly from the substrate through the insulating material;
a source/drain (S/D) feature disposed between the first and second fin structures; and
an isolation trench structure extending through the first fin structure and into the substrate,
wherein the isolation trench structure has a doped sidewall region disposed between and in contact with the S/D feature and the isolation trench structure.

2. The semiconductor device structure of claim 1, wherein the doped sidewall region comprises dopants from Group III elements.

3. The semiconductor device structure of claim 2, wherein the doped sidewall region has a first concentration of boron.

4. The semiconductor device structure of claim 3, further comprising:
a dielectric spacer in the doped sidewall region, wherein the dielectric spacer has a second concentration of boron that is less than the first concentration of boron.

5. The semiconductor device structure of claim 1, wherein the doped sidewall region has a first bottom at a first elevation, and the S/D feature has a second bottom at a second elevation that is substantially the same as the first elevation.

6. A method for forming a semiconductor device structure, comprising:
forming a plurality of fin structures from a substrate, each fin structure comprising a plurality of semiconductor layers and a plurality of sacrificial layers alternatingly stacked;
forming source/drain (S/D) features on opposite sides of the fin structure;
forming an isolation trench between two adjacent S/D features by removing exposed portions of the semiconductor layers and the sacrificial layers;
subjecting the isolation trench to a doping process to form a doped region in a sidewall of the isolation trench; and
filling the isolation trench with a dielectric material.

7. The method of claim 6, wherein the doping process is a plasma doping process or an implantation process.

8. The method of claim 6, wherein the doped region comprises Group III elements.

9. The method of claim 8, wherein the doping process is performed by exposing the isolation trench to a plasma formed from diborane (B₂H₆), boron trichloride (BCl₃), borane (BH₃), boron tribromide (BBr₃), boron trifluoride (BF₃), triethyl borate (TEB), borazine (B₃N₃H₆), or an alkyl-substituted derivative of borazine, or a combination thereof.

10. The method of claim 6, wherein the exposed portions of the semiconductor layers and the sacrificial layers are removed by a plasma etch process using etchants comprising a halogen group.

11. The method of claim 6, wherein the sacrificial layers comprise silicon germanium.

12. The method of claim 6, wherein the sacrificial layers comprise a dielectric.

13. A method for forming a semiconductor device structure, comprising:
forming a plurality of fin structures from a substrate, each fin structure comprising a plurality of semiconductor layers and a plurality of sacrificial layers alternatingly stacked;
forming an insulating material on the substrate;
forming a sacrificial gate structure on the insulating material and over a portion of the fin structures;
forming a source/drain (S/D) feature on opposite sides of each fin structure;
forming a first portion of an isolation trench by removing portions of the sacrificial gate structure and the sacrificial layers to expose the plurality of semiconductor layers of a first fin structure;
exposing the isolation trench to a pre-treatment process;
forming a second portion of the isolation trench by removing the first fin structure and a portion of the substrate; and
filling the isolation trench with a dielectric material.

14. The method of claim 13, further comprising:
prior to forming the S/D feature, removing edges of each sacrificial layer to form cavities; and
forming a dielectric layer in the cavities to form dielectric spacers.

15. The method of claim 14, wherein the pre-treatment process is a doping process using a dopant gas comprising boron.

16. The method of claim 15, wherein the pre-treatment process forms a doped region in a sidewall of the first portion of the isolation trench, and the doped region comprises the semiconductor layers and the dielectric spacers.

17. The method of claim 16, wherein the semiconductor layers have a first concentration of boron and the dielectric spacers have a second concentration of boron that is less than the first concentration of boron.

18. The method of claim 13, wherein the first and second portions of the isolation trenches are formed by an etchant comprising a bromine-based etch chemistry.

19. The method of claim 13, wherein the first portion of the isolation trench has a first bottom at a first elevation, and the S/D feature has a second bottom at a second elevation that is substantially the same as the first elevation.

20. The method of claim 13, further comprising:
while forming a second portion of the isolation trench, exposing the isolation trench to a dopant gas comprising boron.
